(19) United States
(12) Patent Application Publication
(10) Pub. No.: US 2026/0334222 A1
(43) Pub. Date: Oct. 22, 2026

(54) SEMICONDUCTOR DEVICE, INVERTER DEVICE, METHOD FOR MANUFACTURING INVERTER DEVICE, AND VEHICLE

(71) Applicant: ROHM CO., LTD., Kyoto-shi (JP)

(72) Inventor: Takayuki ISHIHARA, Kyoto-shi (JP)

(21) Appl. No.: 19/694,354

(22) Filed: Jun. 1, 2026

Related U.S. Application Data
(63) Continuation of application No. PCT/JP2024/041153, filed on Nov. 20, 2024.

(30) Foreign Application Priority Data
Dec. 8, 2023 (JP) 2023-207395

(51) Int. Cl. H10W 40/20; B60L 15/00; H02M 7/00; H10D 80/20; H10D 80/30; H10W 40/00; H10W 70/04; H10W 70/40; H10W 90/00

(52) U.S. Cl. CPC H10W 40/235; B60L 15/007; H02M 7/003; H10D 80/251; H10D 80/30; H10W 40/037; H10W 70/041; H10W 70/461; H10W 90/736; B60L 2240/525; H10W 70/481

(57) ABSTRACT

A semiconductor device includes a base material, a first conductive layer, a first semiconductor element, and a bonding material. The base material includes a heat dissipation layer. The first conductive layer is bonded to the base material. The first semiconductor element is bonded to the first conductive layer. The bonding material is located on a side opposite to the first conductive layer with respect to the base material in a first direction and is disposed on the heat dissipation layer. The bonding material includes metal particles. As an example, the semiconductor device further includes a sealing resin covering the first semiconductor element.

### TECHNICAL FIELD

The present disclosure relates to a semiconductor device. The present disclosure also relates to an inverter device including the semiconductor device and a method for manufacturing the inverter device. The present disclosure further relates to a vehicle in which the semiconductor device is installed.

### BACKGROUND ART

Conventionally, semiconductor devices on which semiconductor elements having a switching function (MOSFETs, IGBTs, and the like) are mounted have been widely known, and are mainly used for power conversion. WO-2023/047890-A1 discloses an example of such a semiconductor device. The semiconductor device disclosed in the document includes a sealing resin covering the semiconductor elements, a heat sink, and an attachment member. The attachment member is a plate spring. The sealing resin is attached to the heat sink through the attachment member. The sealing resin is sandwiched between the heat sink and the attachment member.

Apart from the semiconductor device disclosed in WO-2023/047890-A1, there are cases in which a base material of a semiconductor device is bonded to a heat sink via a bonding layer. The base material supports a semiconductor element and is exposed from the sealing resin. For example, the bonding layer is a sintered body of metal particles. In such a case, the bonding layer is formed by sintering a bonding material including metal particles. The bonding material is disposed on the heat sink or the base material. At this time, if a defect or other failure occurs in the disposed bonding material, the base material may be peeled from the heat sink after the bonding layer is formed by sintering.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, in which a sealing resin is shown transparently.

FIG. 4 is a partially enlarged view of FIG. 3.

FIG. 5 is a plan view corresponding to FIG. 2, in which a first conductive member is shown transparently, and a sealing resin and a second conductive member are omitted.

FIG. 6 is a right-side view of the semiconductor device shown in FIG. 1.

FIG. 7 is a bottom view of the semiconductor device shown in FIG. 1.

FIG. 8 is a sectional view taken along line VIII-VIII in FIG. 3.

FIG. 9 is a sectional view taken along line IX-IX in FIG. 3.

FIG. 10 is a partially enlarged view of the first semiconductor element and its peripheral part shown in FIG. 9.

FIG. 11 is a partially enlarged view of the second semiconductor element and its peripheral part shown in FIG. 9.

FIG. 12 is a sectional view taken along line XII-XII in FIG. 3.

FIG. 13 is a sectional view taken along line XIII-XIII in FIG. 3.

FIG. 14 is a partially enlarged view of FIG. 10.

FIG. 15 is a bottom view of a semiconductor device according to a variation of the first embodiment of the present disclosure.

FIG. 16 is a plan view of an inverter device including the semiconductor device shown in FIG. 1.

FIG. 17 is a partially enlarged view of FIG. 16.

FIG. 18 is a front view of the inverter device shown in FIG. 16, corresponding to FIG. 17.

FIG. 19 is a sectional view of the inverter device shown in FIG. 16, corresponding to FIG. 9.

FIG. 20 is a partially enlarged view of FIG. 19.

FIG. 21 is a circuit block diagram of the inverter device shown in FIG. 16.

FIG. 22 is a partially enlarged view of FIG. 21.

FIG. 23 is a circuit block diagram of each of a plurality of drive circuits included in circuit shown in FIG. 21.

FIG. 24 is a sectional view illustrating a first step in a manufacture of the inverter device shown in FIG. 16.

FIG. 25 is a sectional view illustrating a second step in the manufacture of the inverter device shown in FIG. 16.

FIG. 26 is a sectional view illustrating a third step in the manufacture of the inverter device shown in FIG. 16.

FIG. 27 is a sectional view illustrating a fourth step in the manufacture of the inverter device shown in FIG. 16.

FIG. 28 is a sectional view illustrating a fifth step in the manufacture of the inverter device shown in FIG. 16.

FIG. 29 is a sectional view illustrating a sixth step in the manufacture of the inverter device shown in FIG. 16.

FIG. 30 is a schematic view of a vehicle on which the semiconductor device shown in FIG. 1 is installed.

FIG. 31 is a bottom view of a semiconductor device according to a second embodiment of the present disclosure.

FIG. 32 is a sectional view of the semiconductor device shown in FIG. 31, corresponding to FIG. 9.

FIG. 33 is a sectional view of a semiconductor device according to a third embodiment of the present disclosure, corresponding to FIG. 9.

FIG. 34 is a partially enlarged view of FIG. 33.

FIG. 35 is a bottom view of a semiconductor device according to a fourth embodiment of the present disclosure.

FIG. 36 is a sectional view of the semiconductor device shown in FIG. 35, corresponding to FIG. 9.

FIG. 37 is a sectional view illustrating a manufacturing step of an inverter device including the semiconductor device shown in FIG. 35.

### DETAILED DESCRIPTION

Details of the present disclosure will be described below with reference to the accompanying drawings.

### First Embodiment

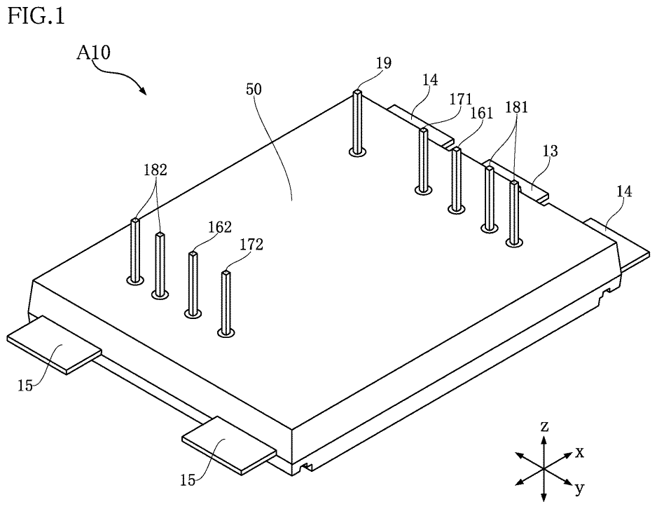

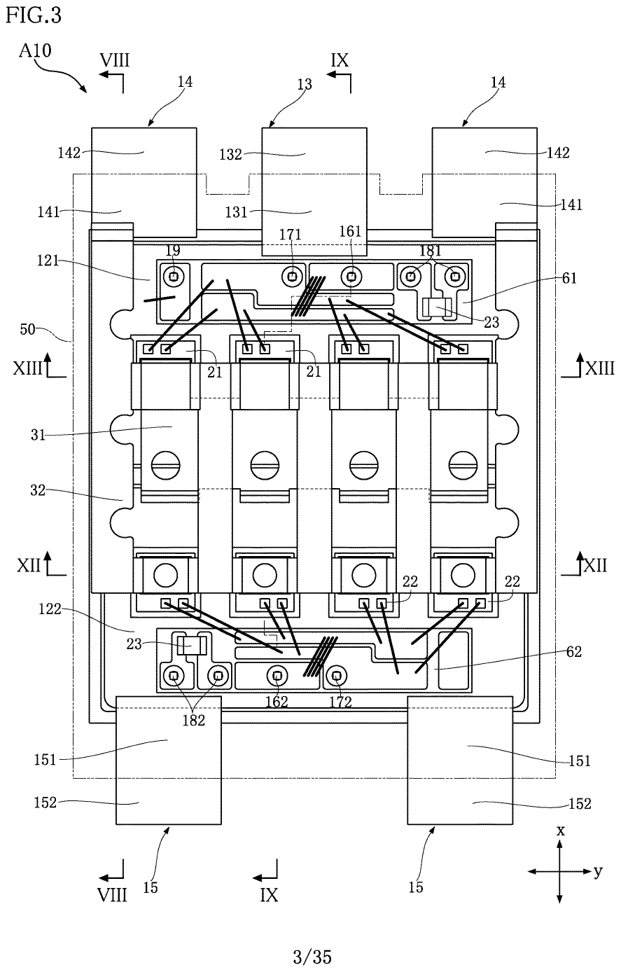

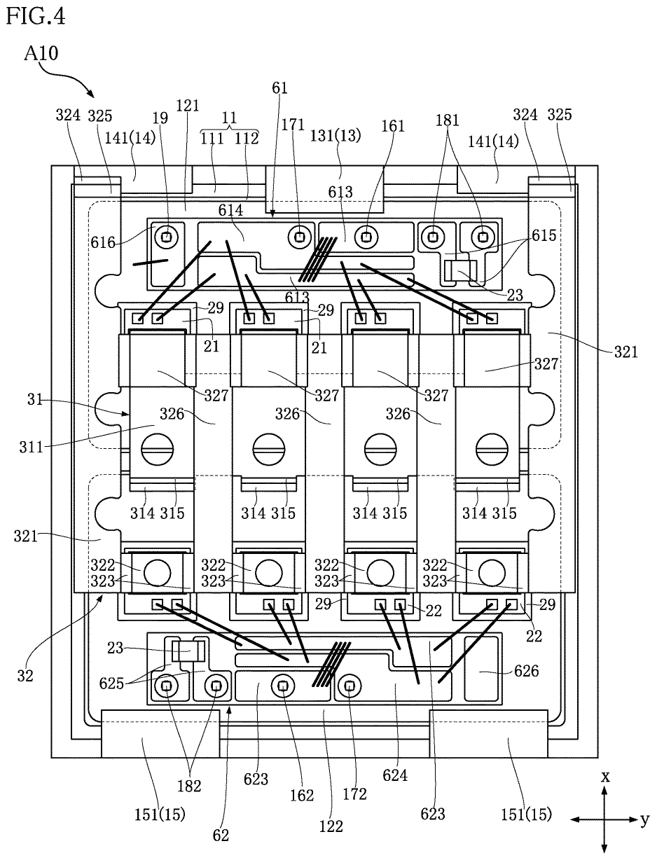

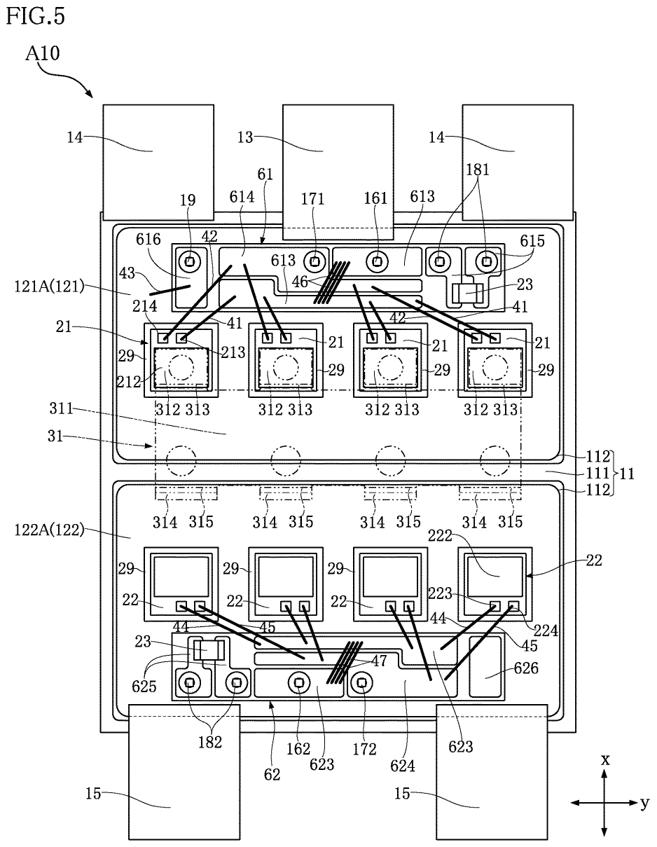

A semiconductor device A10 according to a first embodiment of the present disclosure will be described below with reference to FIGS. 1 to 14. The semiconductor device A10 includes a base material 11, a first conductive layer 121, a second conductive layer 122, a first power terminal 13, two second power terminals 14, two third power terminals 15, a plurality of first semiconductor elements 21, a plurality of second semiconductor elements 22, a first conductive member 31, a second conductive member 32, a sealing resin 50, and a bonding material 79. The semiconductor device A10 further includes a first signal terminal 161, a second signal terminal 162, a third signal terminal 171, a fourth signal terminal 172, two fifth signal terminals 181, two sixth signal terminals 182, a seventh signal terminal 19, two thermistors 23, a first wiring 61, and a second wiring 62. For convenience of understanding, in FIGS. 3 and 4, the sealing resin 50 is shown transparently. In FIG. 3, the sealing resin 50 shown transparently is indicated by imaginary lines (two-dot chain lines). In FIG. 5, for convenience of understanding, the first conductive member 31 is shown transparently, and the second conductive member 32 and the sealing resin 50 are omitted.

In the description of the semiconductor device A10, for convenience, a normal direction of a first obverse surface 121A of the first conductive layer 121, which will be described later, is referred to as a “first direction z”. One direction orthogonal to the first direction z is referred to as a “second direction x”. A direction orthogonal to the first direction z and the second direction x is referred to as a “third direction y”.

The semiconductor device A10 converts DC power input to the first power terminal 13 and the two second power terminals 14 into AC power through the first semiconductor elements 21 and the second semiconductor elements 22. The converted AC power is output from each of the two third power terminals 15 to a power supply target (e.g., a motor 89 described later).

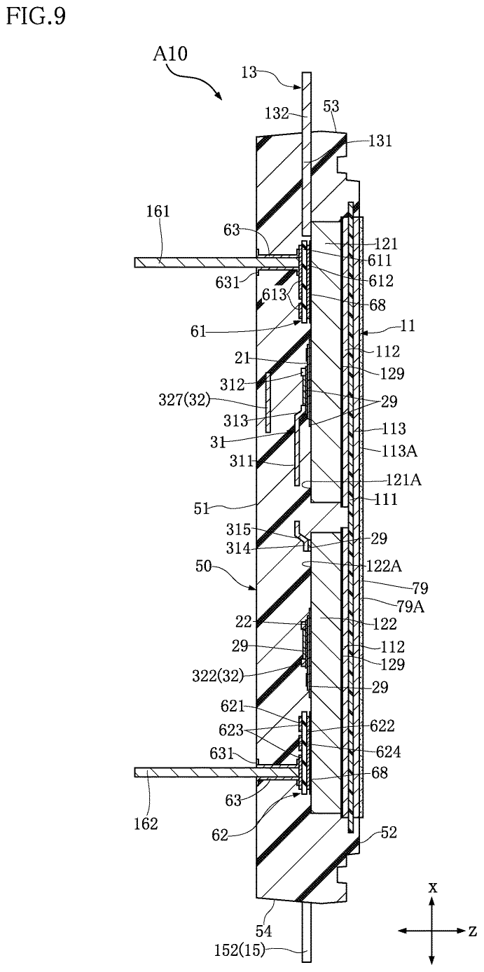

As shown in FIGS. 9 to 11, the base material 11 is located on a side opposite to the first semiconductor elements 21 and the second semiconductor elements 22 with respect to the first conductive layer 121 and the second conductive layer 122 in the first direction z. The base material 11 supports the first conductive layer 121 and the second conductive layer 122. In the semiconductor device A10, the base material 11 is composed of, for example, a substrate formed by active metal brazing (AMB). As shown in FIGS. 9 to 11, the base material 11 includes an insulating layer 111, two support layers 112, and a heat dissipation layer 113. The base material 11 is covered with the sealing resin 50 except for a part of the heat dissipation layer 113.

As shown in FIGS. 9 to 11, the insulating layer 111 includes a portion interposed between the support layers 112 and the heat dissipation layer 113 in the first direction z. The insulating layer 111 is made of a material having relatively high thermal conductivity. The insulating layer 111 is made of, for example, ceramics containing aluminum nitride (AlN). Alternatively, the insulating layer 111 may be made of an insulating resin sheet. The insulating layer 111 has a dimension in the first direction z smaller than a dimension of each of the first conductive layer 121 and the second conductive layer 122 in the first direction z.

As shown in FIGS. 9 to 11, the two support layers 112 are located, in the first direction z, between the insulating layer 111 and the first conductive layer 121 and between the insulating layer 111 and the second conductive layer 122. The support layers 112 are spaced apart from each other in the second direction x. The support layers 112 each contain copper (Cu). As shown in FIG. 5, as viewed in the first direction z, the support layers 112 are located inward of a peripheral edge of the insulating layer 111.

As shown in FIGS. 9 to 11, the heat dissipation layer 113 is located on a side opposite to the two support layers 112 with respect to the insulating layer 111 in the first direction z. The heat dissipation layer 113 contains copper. The heat dissipation layer 113 has a dimension in the first direction z larger than a dimension of the insulating layer 111 in the first direction z. As viewed in the first direction z, the heat dissipation layer 113 is located inward of the peripheral edge of the insulating layer 111. The heat dissipation layer 113 includes a heat dissipation surface 113A facing away from the insulating layer 111 in the first direction z. The heat dissipation surface 113A is exposed from the sealing resin 50.

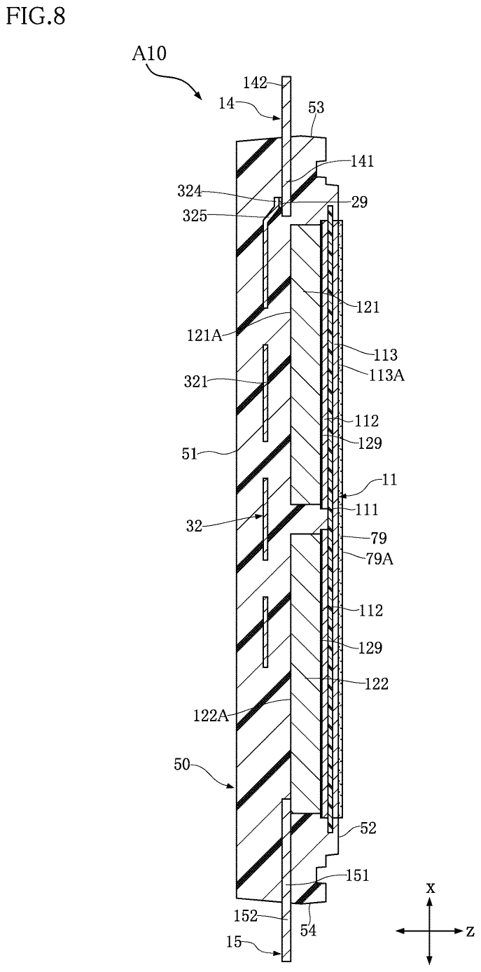

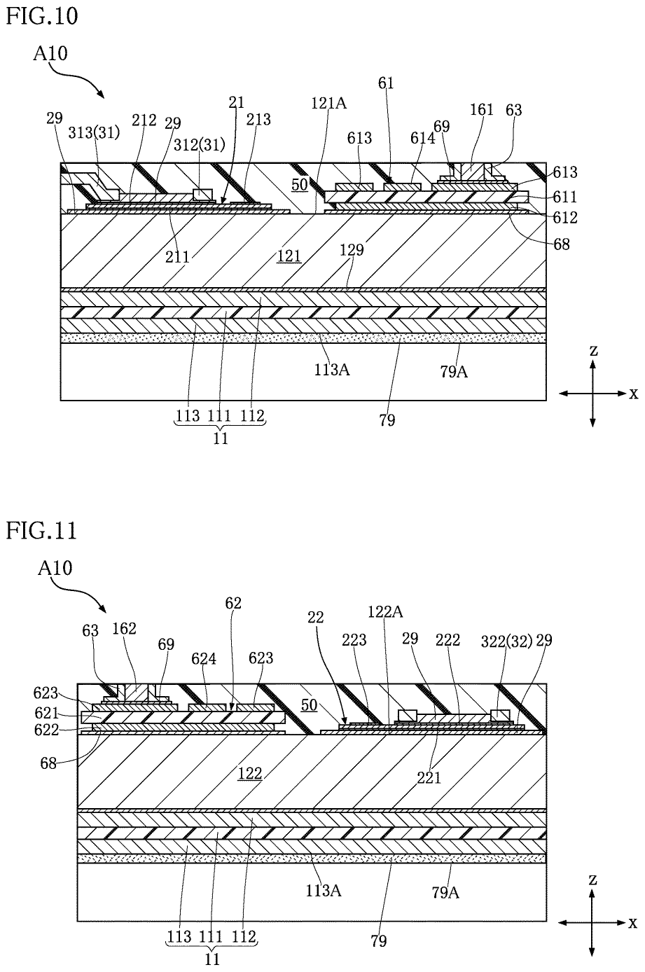

As shown in FIGS. 9 to 11, the first conductive layer 121 and the second conductive layer 122 are bonded to the base material 11. The first conductive layer 121 and the second conductive layer 122 each contain copper. The first conductive layer 121 and the second conductive layer 122 are spaced apart from each other in the second direction x. As shown in FIGS. 8 and 9, the first conductive layer 121 includes a first obverse surface 121A facing the first direction z. The first obverse surface 121A faces the first semiconductor elements 21. As shown in FIG. 10, the first conductive layer 121 is bonded to one of the two support layers 112 through a first bonding layer 129. The first bonding layer 129 is, for example, solder. As shown in FIGS. 8 and 9, the second conductive layer 122 includes a second obverse surface 122A facing the same side as the first obverse surface 121A in the first direction z. The second obverse surface 122A faces the second semiconductor elements 22. As shown in FIG. 11, the second conductive layer 122 is bonded to the other of the two support layers 112 through a first bonding layer 129.

As shown in FIGS. 5 and 9, the first semiconductor elements 21 are bonded to the first obverse surface 121A of the first conductive layer 121. The first semiconductor elements 21 are arranged along the third direction y. The second semiconductor elements 22 are bonded to the second obverse surface 122A of the second conductive layer 122. The second semiconductor elements 22 are arranged along the third direction y. The first semiconductor elements 21 and the second semiconductor elements 22 are, for example, MOSFETs (Metal-Oxide-Semiconductor Field-Effect Transistors). Alternatively, the first semiconductor elements 21 and the second semiconductor elements 22 may be switching elements such as IGBTs (Insulated Gate Bipolar Transistors). As another example, the first semiconductor elements 21 may include switching elements and freewheeling diodes individually connected in parallel to the switching elements. Similarly, the second semiconductor elements 22 may include switching elements and freewheeling diodes individually connected in parallel to the switching elements. Each freewheeling diode is, for example, a Schottky barrier diode. In the description of the semiconductor device A10, the first semiconductor elements 21 and the second semiconductor elements 22 are assumed to be n-channel type MOSFETs of a vertical structure. Each of the first semiconductor elements 21 and the second semiconductor elements 22 includes a compound semiconductor substrate. The compound semiconductor substrate contains silicon carbide (SiC).

As shown in FIGS. 5 and 10, each first semiconductor element 21 includes a first electrode 211, a second electrode 212, a first gate electrode 213, and a first detection electrode 214.

As shown in FIG. 10, each first electrode 211 faces the first obverse surface 121A of the first conductive layer 121. A current corresponding to electric power before conversion in the corresponding first semiconductor element 21 flows through the first electrode 211. That is, the first electrode 211 corresponds to a drain electrode of the corresponding first semiconductor element 21. Each first electrode 211 is conductively bonded to the first obverse surface 121A through a conductive bonding layer 29. Hence, the first electrode 211 of each first semiconductor element 21 is electrically connected to the first conductive layer 121. The conductive bonding layer 29 is a sintered body of metal particles including silver (Ag) or the like. Alternatively, the conductive bonding layer 29 may be solder.

As shown in FIG. 10, each second electrode 212 is located, in the first direction z, on the side of the corresponding first semiconductor element 21 opposite to the first obverse surface 121A of the first conductive layer 121. Hence, the first electrode 211 and the second electrode 212 of each first semiconductor element 21 are located opposite to each other in the first direction z. A current corresponding to electric power after conversion in the corresponding first semiconductor element 21 flows through the second electrode 212. That is, the second electrode 212 corresponds to a source electrode of the corresponding first semiconductor element 21.

As shown in FIG. 10, each first gate electrode 213 is located, in the first direction z, on side of the corresponding first semiconductor element 21 opposite to the first obverse surface 121A of the first conductive layer 121. Hence, each first gate electrode 213 is located on the same side as the corresponding second electrode 212 in the first direction z. Each first gate electrode 213 receives a gate voltage for driving the corresponding first semiconductor element 21. As shown in FIG. 5, as viewed in the first direction z, each first gate electrode 213 has an area smaller than an area of the corresponding second electrode 212.

As shown in FIG. 5, each first detection electrode 214 is located, in the first direction z, on the same side as the corresponding second electrode 212 and the corresponding first gate electrode 213. Each first detection electrode 214 is adjacent to the corresponding first gate electrode 213 in the third direction y. Each first detection electrode 214 receives a voltage equivalent to a voltage applied to the corresponding second electrode 212. As viewed in the first direction z, each first detection electrode 214 has an area substantially equal to an area of the corresponding first gate electrode 213.

As shown in FIGS. 5 and 11, each second semiconductor element 22 includes a third electrode 221, a fourth electrode 222, a second gate electrode 223, and a second detection electrode 224.

As shown in FIG. 11, each third electrode 221 faces the second obverse surface 122A of the second conductive layer 122. A current corresponding to electric power before conversion in the corresponding second semiconductor element 22 flows through the third electrode 221. That is, the third electrode 221 corresponds to a drain electrode of the corresponding second semiconductor element 22. Each third electrode 221 is conductively bonded to the second obverse surface 122A through a conductive bonding layer 29. Hence, the third electrode 221 of each second semiconductor element 22 is electrically connected to the second conductive layer 122.

As shown in FIG. 11, each fourth electrode 222 is located, in the first direction z, on the side of the corresponding second semiconductor element 22 opposite to the second obverse surface 122A of the second conductive layer 122. Hence, the third electrode 221 and the fourth electrode 222 of each second semiconductor element 22 are located opposite to each other in the first direction z. A current corresponding to electric power after conversion in the corresponding second semiconductor element 22 flows through the fourth electrode 222. That is, the fourth electrode 222 corresponds to a source electrode of the corresponding second semiconductor element 22.

As shown in FIG. 11, each second gate electrode 223 is located, in the first direction z, on the side of the corresponding second semiconductor element 22 opposite to the second obverse surface 122A of the second conductive layer 122. Hence, each second gate electrode 223 is located on the same side as the corresponding fourth electrode 222 in the first direction z. Each second gate electrode 223 receives a gate voltage for driving the corresponding second semiconductor element 22. As shown in FIG. 5, as viewed in the first direction z, each second gate electrode 223 has an area smaller than an area of the corresponding fourth electrode 222.

As shown in FIG. 5, each second detection electrode 224 is located, in the first direction z, on the same side as the corresponding fourth electrode 222 and the corresponding second gate electrode 223. Each second detection electrode 224 is adjacent to the corresponding second gate electrode 223 in the third direction y. Each second detection electrode 224 receives a voltage equivalent to a voltage applied to the corresponding fourth electrode 222. As viewed in the first direction z, each second detection electrode 224 has an area substantially equal to an area of the corresponding second gate electrode 223.

As shown in FIGS. 3 and 9, the first power terminal 13 is located on a side opposite to the second conductive layer 122 with respect to the first conductive layer 121 in the second direction x. The first power terminal 13 is conductively bonded to the first conductive layer 121. Hence, the first power terminal 13 is electrically connected to the first electrode 211 of each first semiconductor element 21 through the first conductive layer 121. The first power terminal 13 is a P terminal (positive electrode) to which DC power to be converted is input. The first power terminal 13 extends from the first conductive layer 121 in the second direction x. The first power terminal 13 includes a covered portion 131 and an exposed portion 132. As shown in FIG. 9, the covered portion 131 is conductively bonded to the first conductive layer 121 and is covered with the sealing resin 50. The exposed portion 132 extends from the covered portion 131 in the second direction x and is exposed to the outside from the sealing resin 50.

As shown in FIGS. 3 and 8, each of the two second power terminals 14 is located on the same side as the first power terminal 13 with respect to the first conductive layer 121 and the second conductive layer 122 in the second direction x, and is spaced apart from the first conductive layer 121 and the second conductive layer 122. Each of the two second power terminals 14 is electrically connected to the fourth electrode 222 of each second semiconductor element 22. The two second power terminals 14 are N terminals (negative electrodes) to which DC power to be converted is input. The second power terminals 14 are spaced apart from each other in the third direction y. The first power terminal 13 is located between the two second power terminals 14 in the third direction y. Each of the two second power terminals 14 includes a covered portion 141 and an exposed portion 142. As shown in FIG. 8, each covered portion 141 is spaced apart from the first conductive layer 121 and is covered with the sealing resin 50. Each exposed portion 142 extends from the corresponding covered portion 141 in the second direction x and is exposed to the outside from the sealing resin 50.

As shown in FIGS. 3 and 8, each of the two third power terminals 15 is located on a side opposite to the first conductive layer 121 with respect to the second conductive layer 122 in the second direction x. Each of the two third power terminals 15 is conductively bonded to the second conductive layer 122. Hence, each of the two third power terminals 15 is electrically connected to the third electrode 221 of each second semiconductor element 22 through the second conductive layer 122. AC power converted in the first semiconductor elements 21 and the second semiconductor elements 22 is output from each of the two third power terminals 15. In the semiconductor device A10, the two third power terminals 15 are spaced apart from each other in the third direction y. Each of the two third power terminals 15 includes a covered portion 151 and an exposed portion 152. As shown in FIG. 8, each covered portion 151 is conductively bonded to the second conductive layer 122 and is covered with the sealing resin 50. Each exposed portion 152 extends from the corresponding covered portion 151 in the second direction x and is exposed to the outside from the sealing resin 50.

As shown in FIG. 10, the first wiring 61 is bonded to the first obverse surface 121A of the first conductive layer 121. The first wiring 61 is located on a side opposite to the second semiconductor elements 22 with respect to the first semiconductor elements 21 in the second direction x. The first wiring 61 is electrically connected to the first semiconductor elements 21 and the first conductive layer 121. As shown in FIGS. 5 and 10, the first wiring 61 includes a first mounting layer 611, a first metal layer 612, two first gate wiring layers 613, a first detection wiring layer 614, a first temperature detection wiring layer 615, and a second detection wiring layer 616.

As shown in FIG. 5, the first mounting layer 611 carries the two first gate wiring layers 613, the first detection wiring layer 614, two first temperature detection wiring layers 615, and the second detection wiring layer 616. The first mounting layer 611 is an insulator. The first mounting layer 611 is made of, for example, ceramics. Alternatively, the first mounting layer 611 may be made of an insulating resin sheet.

As shown in FIG. 10, the first metal layer 612 is located, in the first direction z, on a side facing the first obverse surface 121A of the first conductive layer 121 with respect to the first mounting layer 611. The first metal layer 612 is bonded to the first mounting layer 611. The first metal layer 612 contains copper. The first metal layer 612 is bonded to the first obverse surface 121A through a second bonding layer 68. The second bonding layer 68 is, for example, solder.

As shown in FIGS. 5 and 10, the two first gate wiring layers 613 are located on a side opposite to the first metal layer 612 with respect to the first mounting layer 611. The two first gate wiring layers 613 are bonded to the first mounting layer 611. One of the two first gate wiring layers 613 has a plurality of first wires 41 conductively bonded thereto. The first wires 41 are conductively bonded to the first gate electrodes 213 of the first semiconductor elements 21, respectively. Further, a plurality of sixth wires 46 are conductively bonded to the two first gate wiring layers 613. Hence, each of the two first gate wiring layers 613 is electrically connected to the first gate electrode 213 of each first semiconductor element 21.

As shown in FIGS. 5 and 10, the first detection wiring layer 614 is located on a side opposite to the first metal layer 612 with respect to the first mounting layer 611. The first detection wiring layer 614 is bonded to the first mounting layer 611. A plurality of second wires 42 are conductively bonded to the first detection wiring layer 614. Further, the second wires 42 are conductively bonded to the first detection electrodes 214 of the first semiconductor elements 21, respectively. Hence, the first detection wiring layer 614 is electrically connected to the first detection electrode 214 of each first semiconductor element 21.

As shown in FIG. 5, the two first temperature detection wiring layers 615 are located on a side opposite to the first metal layer 612 with respect to the first mounting layer 611. The two first temperature detection wiring layers 615 are bonded to the first mounting layer 611. The two first temperature detection wiring layers 615 are adjacent to each other in the third direction y.

As shown in FIG. 5, the second detection wiring layer 616 is located on a side opposite to the first metal layer 612 with respect to the first mounting layer 611. The second detection wiring layer 616 is bonded to the first mounting layer 611. A third wire 43 is conductively bonded to the second detection wiring layer 616. Further, the third wire 43 is conductively bonded to the first obverse surface 121A of the first conductive layer 121. Hence, the second detection wiring layer 616 is electrically connected to the first conductive layer 121.

As shown in FIG. 11, the second wiring 62 is bonded to the second obverse surface 122A of the second conductive layer 122. The second wiring 62 is located on a side opposite to the first semiconductor elements 21 with respect to the second semiconductor elements 22 in the second direction x. The second wiring 62 is electrically connected to the second semiconductor elements 22 and the second conductive layer 122. As shown in FIGS. 5 and 11, the second wiring 62 includes a second mounting layer 621, a second metal layer 622, two second gate wiring layers 623, a third detection wiring layer 624, two second temperature detection wiring layers 625, and a fourth detection wiring layer 626.

As shown in FIG. 5, the second mounting layer 621 carries the two second gate wiring layers 623, the third detection wiring layer 624, two second temperature detection wiring layers 625, and the fourth detection wiring layer 626. The second mounting layer 621 is an insulator. The second mounting layer 621 is made of, for example, ceramics. Alternatively, the second mounting layer 621 may be made of an insulating resin sheet.

As shown in FIG. 11, the second metal layer 622 is located, in the first direction z, on a side facing the second obverse surface 122A of the second conductive layer 122 with respect to the second mounting layer 621. The second metal layer 622 is bonded to the second mounting layer 621. The second metal layer 622 contains copper. The second metal layer 622 is bonded to the second obverse surface 122A through the second bonding layer 68.

As shown in FIGS. 5 and 11, the two second gate wiring layers 623 are located on a side opposite to the second metal layer 622 with respect to the second mounting layer 621. The two second gate wiring layers 623 are bonded to the second mounting layer 621. One of the two second gate wiring layers 623 has a plurality of fourth wires 44 conductively bonded thereto. The fourth wires 44 are conductively bonded to the second gate electrodes 223 of the second semiconductor elements 22, respectively. Further, a plurality of seventh wires 47 are conductively bonded to the two second gate wiring layers 623. Hence, each of the two second gate wiring layers 623 is electrically connected to the second gate electrode 223 of each second semiconductor element 22.

As shown in FIGS. 5 and 11, the third detection wiring layer 624 is located on a side opposite to the second metal layer 622 with respect to the second mounting layer 621. The third detection wiring layer 624 is bonded to the second mounting layer 621. A plurality of fifth wires 45 are conductively bonded to the third detection wiring layer 624. Further, the fifth wires 45 are conductively bonded to the second detection electrodes 224 of the second semiconductor elements 22, respectively. Hence, the third detection wiring layer 624 is electrically connected to the second detection electrode 224 of each second semiconductor element 22.

As shown in FIG. 5, the two second temperature detection wiring layers 625 are located on a side opposite to the second metal layer 622 with respect to the second mounting layer 621. The two second temperature detection wiring layers 625 are bonded to the second mounting layer 621. The two second temperature detection wiring layers 625 are adjacent to each other in the third direction y.

As shown in FIG. 5, the fourth detection wiring layer 626 is located on a side opposite to the second metal layer 622 with respect to the second mounting layer 621. The fourth detection wiring layer 626 is bonded to the second mounting layer 621.

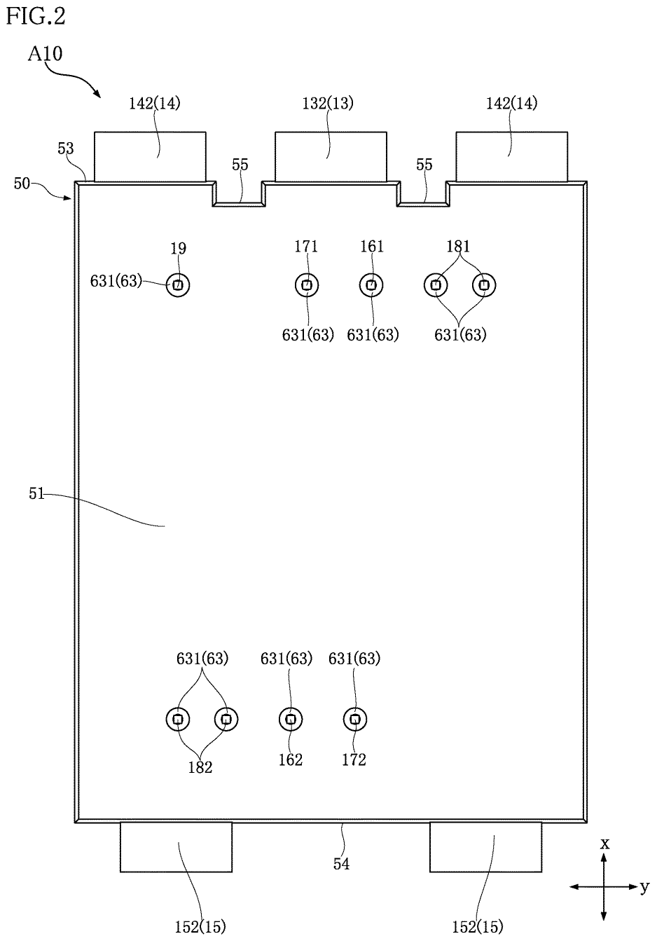

As shown in FIGS. 10 and 11, each of the sleeves 63 is conductively bonded to one of the first wiring 61 and the second wiring 62 through a third bonding layer 69. The third bonding layer 69 is, for example, solder. The sleeves 63 are each made of a conductive material such as metal. Each sleeve 63 has a tubular shape extending in the first direction z. As shown in FIGS. 2 and 9, each sleeve 63 includes an end surface 631 facing the same side as the first obverse surface 121A of the first conductive layer 121 in the first direction z. Each end surface 631 is exposed from a top surface 51 of the sealing resin 50, which will be described later. The third bonding layer 69 is, for example, solder.

As shown in FIG. 4, one of the two thermistors 23 is conductively bonded to the two first temperature detection wiring layers 615 of the first wiring 61. As shown in FIG. 4, the other of the two thermistors 23 is conductively bonded to the two second temperature detection wiring layers 625 of the second wiring 62. The two thermistors 23 serve as temperature detection sensors for the semiconductor device A10.

As shown in FIG. 1, the first signal terminal 161, the second signal terminal 162, the third signal terminal 171, the fourth signal terminal 172, the two fifth signal terminals 181, the two sixth signal terminals 182, and the seventh signal terminal 19 are formed of metal pins extending in the first direction z. These terminals project from a top surface 51 of the sealing resin 50, which will be described later. Further, these terminals are individually press-fitted into the sleeves 63. Hence, each of these terminals is supported by the corresponding one of the sleeves 63 and is electrically connected to one of the first wiring 61 and the second wiring 62.

As shown in FIGS. 5 and 10, the first signal terminal 161 is press-fitted into one of the sleeves 63 that is conductively bonded to one of the two first gate wiring layers 613 of the first wiring 61. Hence, the first signal terminal 161 is electrically connected, through the two first gate wiring layers 613, to the first gate electrode 213 of each first semiconductor element 21. The first signal terminal 161 receives a gate voltage for driving the first semiconductor elements 21.

As shown in FIGS. 5 and 11, the second signal terminal 162 is press-fitted into one of the sleeves 63 that is conductively bonded to one of the two second gate wiring layers 623 of the second wiring 62. Hence, the second signal terminal 162 is electrically connected, through the two second gate wiring layers 623, to the second gate electrode 223 of each second semiconductor element 22. The second signal terminal 162 receives a gate voltage for driving the second semiconductor elements 22.

As shown in FIG. 2, the third signal terminal 171 is adjacent to the first signal terminal 161 in the third direction y. As shown in FIG. 5, the third signal terminal 171 is press-fitted into one of the sleeves 63 that is conductively bonded to the first detection wiring layer 614 of the first wiring 61. Hence, the third signal terminal 171 is electrically connected, through the first detection wiring layer 614, to the first detection electrode 214 of each first semiconductor element 21. The third signal terminal 171 receives a voltage equivalent to a voltage applied to the first detection electrode 214 of each first semiconductor element 21.

As shown in FIG. 2, the fourth signal terminal 172 is adjacent to the second signal terminal 162 in the third direction y. As shown in FIG. 5, the fourth signal terminal 172 is press-fitted into one of the sleeves 63 that is conductively bonded to the third detection wiring layer 624 of the second wiring 62. Hence, the fourth signal terminal 172 is electrically connected, through the third detection wiring layer 624, to the second detection electrode 224 of each second semiconductor element 22. The fourth signal terminal 172 receives a voltage equivalent to a voltage applied to the second detection electrode 224 of each second semiconductor element 22.

As shown in FIG. 2, the two fifth signal terminals 181 are located on a side opposite to the third signal terminal 171 with respect to the first signal terminal 161 in the third direction y. The two fifth signal terminals 181 are adjacent to each other in the third direction y. As shown in FIG. 5, the two fifth signal terminals 181 are individually press-fitted into two sleeves 63, among the sleeves 63, that are conductively bonded to the respective two first temperature detection wiring layers 615 of the first wiring 61. Hence, the two fifth signal terminals 181 are electrically connected to one of the two thermistors 23 conductively bonded to the two first temperature detection wiring layers 615.

As shown in FIG. 2, the two sixth signal terminals 182 are located on a side opposite to the fourth signal terminal 172 with respect to the second signal terminal 162 in the third direction y. The two sixth signal terminals 182 are adjacent to each other in the third direction y. As shown in FIG. 5, the two sixth signal terminals 182 are individually press-fitted into two sleeves 63, among the sleeves 63, that are conductively bonded to the respective two second temperature detection wiring layers 625 of the second wiring 62. Hence, the two sixth signal terminals 182 are electrically connected to one of the two thermistors 23 that is conductively bonded to the two second temperature detection wiring layers 625.

As shown in FIG. 2, the seventh signal terminal 19 is located on a side opposite to the first signal terminal 161 with respect to the third signal terminal 171 in the third direction y. As shown in FIG. 5, the seventh signal terminal 19 is press-fitted into one of the sleeves 63 that is conductively bonded to the second detection wiring layer 616 of the first wiring 61. Hence, the seventh signal terminal 19 is electrically connected, through the second detection wiring layer 616, to the first conductive layer 121. The seventh signal terminal 19 receives a voltage corresponding to the DC power input to the first power terminal 13 and the two second power terminals 14.

As shown in FIGS. 5 and 10, the first conductive member 31 is conductively bonded to the second electrodes 212 of the first semiconductor elements 21 and to the second obverse surface 122A of the second conductive layer 122. Hence, the second electrode 212 of each first semiconductor element 21 is electrically connected to the second conductive layer 122. The first conductive member 31 contains copper. The first conductive member 31 is a metal clip. As shown in FIG. 5, the first conductive member 31 includes a first main portion 311, a plurality of first bonding portions 312, a plurality of first connecting portions 313, a plurality of second bonding portions 314, and a plurality of second connecting portions 315.

The first main portion 311 forms a main section of the first conductive member 31. As shown in FIG. 5, the first main portion 311 extends in the third direction y. As shown in FIG. 9, the first main portion 311 bridges between the first conductive layer 121 and the second conductive layer 122.

As shown in FIG. 10, the first bonding portions 312 are conductively bonded to the second electrodes 212 of the first semiconductor elements 21, respectively.

As shown in FIG. 5, the first connecting portions 313 are connected to the first main portion 311. In addition, the first connecting portions 313 are individually connected to the first bonding portions 312. The first connecting portions 313 are spaced apart from each other in the third direction y. As shown in FIG. 9, as viewed in the third direction y, each first connecting portion 313 is inclined away from the first obverse surface 121A of the first conductive layer 121 from the corresponding first bonding portion 312 toward the first main portion 311.

As shown in FIGS. 5 and 9, the second bonding portions 314 are conductively bonded to the second obverse surface 122A of the second conductive layer 122. The second bonding portions 314 are arranged along the third direction y.

As shown in FIGS. 5 and 9, the second connecting portions 315 are connected to the first main portion 311. In addition, the second connecting portions 315 are individually connected to the second bonding portions 314. As viewed in the third direction y, each second connecting portion 315 is inclined away from the second obverse surface 122A of the second conductive layer 122 from the corresponding second bonding portion 314 toward the first main portion 311.

As shown in FIGS. 9, 10, and 13, a conductive bonding layer 29 is located between the second electrode 212 of each first semiconductor element 21 and the corresponding one of the first bonding portions 312. The conductive bonding layers 29 conductively bond the first bonding portions 312 and the second electrodes 212 of the first semiconductor elements 21, respectively. As shown in FIG. 9, a conductive bonding layer 29 is located between the second obverse surface 122A of the second conductive layer 122 and each second bonding portion 314. The conductive bonding layers 29 conductively bond the second obverse surface 122A and the second bonding portions 314, respectively.

As shown in FIGS. 4 and 11, the second conductive member 32 is conductively bonded to the fourth electrodes 222 of the second semiconductor elements 22 and to the covered portions 141 of the second power terminals 14. Hence, the fourth electrodes 222 of the second semiconductor elements 22 are electrically connected to the second power terminals 14. The second conductive member 32 contains copper. The second conductive member 32 is a metal clip. As shown in FIG. 4, the second conductive member 32 includes two second main portions 321, a plurality of third bonding portions 322, a plurality of third connecting portions 323, two fourth bonding portions 324, two fourth connecting portions 325, a plurality of intermediate portions 326, and a plurality of beam portions 327.

As shown in FIG. 4, the two second main portions 321 are spaced apart from each other in the third direction y. The two second main portions 321 extend in the second direction x. As shown in FIG. 8, the two second main portions 321 are disposed parallel to the first obverse surface 121A of the first conductive layer 121 and the second obverse surface 122A of the second conductive layer 122. The two second main portions 321 are farther from the first obverse surface 121A and the second obverse surface 122A than the first main portion 311 of the first conductive member 31 is.

As shown in FIG. 4, the intermediate portions 326 are spaced apart from each other in the third direction y and are located between the two second main portions 321 in the third direction y. The intermediate portions 326 each extend in the second direction x. Each of the intermediate portions 326 has a dimension in the second direction x smaller than a dimension of each of the two second main portions 321 in the second direction x.

As shown in FIG. 11, the third bonding portions 322 are conductively bonded to the respective fourth electrodes 222 of the second semiconductor elements 22.

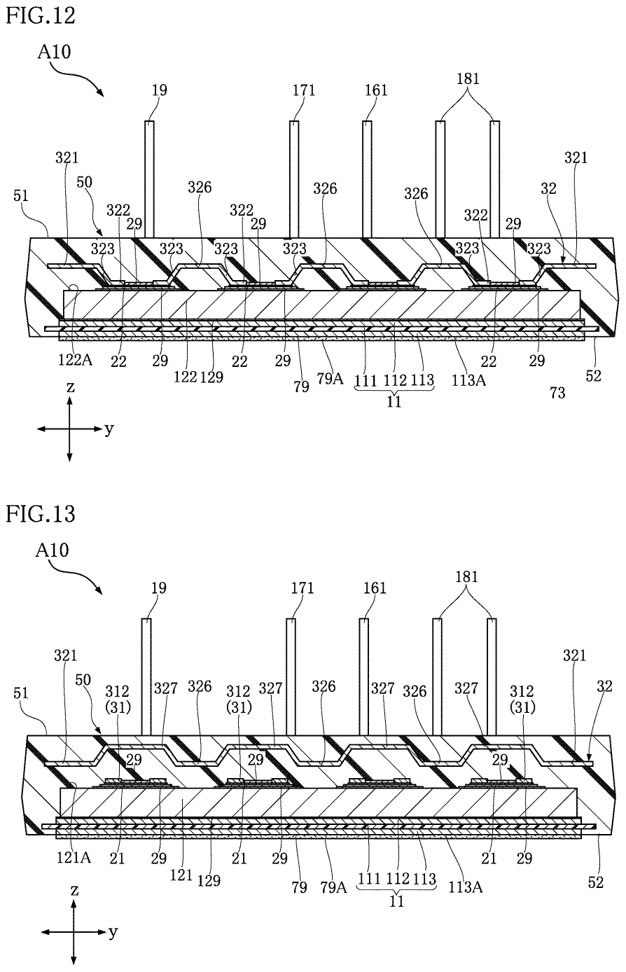

As shown in FIGS. 4 and 12, the third connecting portions 323 are connected to two sides in the third direction y of the third bonding portions 322. Further, each third connecting portion 323 is connected to either one of the two second main portions 321 or one of the intermediate portions 326. As viewed in the second direction x, each third connecting portion 323 is inclined away from the second obverse surface 122A of the second conductive layer 122 from one of the third bonding portions 322 toward either one of the two second main portions 321 or one of the intermediate portions 326.

As shown in FIGS. 4 and 8, the two fourth bonding portions 324 are conductively bonded to the covered portions 141 of the two second power terminals 14, respectively.

As shown in FIGS. 4 and 8, the two fourth connecting portions 325 are individually connected to the two second main portions 321 and the two fourth bonding portions 324. As viewed in the third direction y, each of the two fourth connecting portions 325 is inclined away from the first obverse surface 121A of the first conductive layer 121 from the corresponding one of the two fourth bonding portions 324 toward the corresponding one of the two second main portions 321.

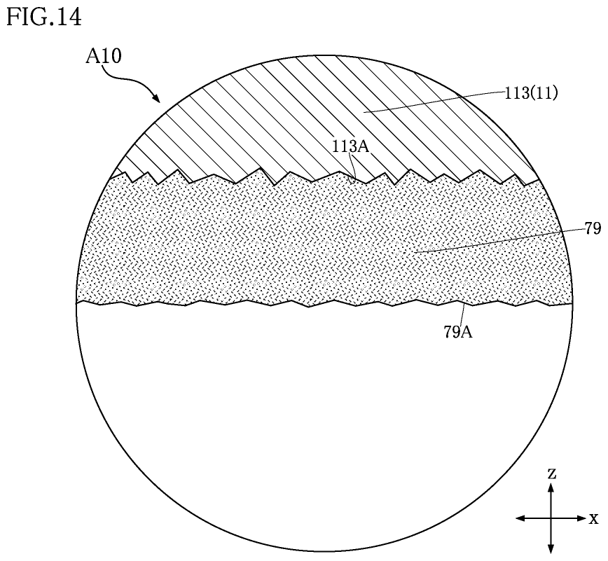

As shown in FIGS. 4 and 13, the beam portions 327 are arranged along the third direction y. As viewed in the first direction z, the beam portions 327 include regions individually overlapping with the first bonding portions 312 of the first conductive member 31. Among the beam portions 327, the beam portions 327 located closer to the center in the third direction y each extend between the intermediate portions 326 in the third direction y. The remaining two beam portions 327 each extend in the third direction y between one o f the two second main portions 321 and the corresponding one of the intermediate portions 326. As viewed in the second direction x, the beam portions 327 have a convex shape toward a side that the first obverse surface 121A of the first conductive layer 121 faces in the first direction z.

As shown in FIGS. 9, 11, and 12, a conductive bonding layer 29 is located between the fourth electrode 222 of each second semiconductor element 22 and the corresponding one of the third bonding portions 322. The conductive bonding layers 29 conductively bond the third bonding portions 322 and the fourth electrodes 222 of the second semiconductor elements 22, respectively. As shown in FIG. 8, a conductive bonding layer 29 is located between the covered portion 141 of each second power terminal 14 and the corresponding one of the fourth bonding portions 324. The conductive bonding layers 29 conductively bond the covered portions 141 of the second power terminals 14 and the fourth bonding portions 324, respectively.

As shown in FIGS. 8, 9, 12, and 13, the sealing resin 50 covers the first conductive layer 121, the second conductive layer 122, the first semiconductor elements 21, the second semiconductor elements 22, the first conductive member 31, and the second conductive member 32. Further, the sealing resin 50 covers a part of each of the base material 11, the first power terminal 13, the third power terminals 15, and the second power terminals 14. The sealing resin 50 has electrical insulating properties. The sealing resin 50 is made of, for example, a material containing a black epoxy resin. As shown in FIGS. 2 and 6 to 9, the sealing resin 50 includes a top surface 51, a bottom surface 52, a first side surface 53, a second side surface 54, and two recesses 55.

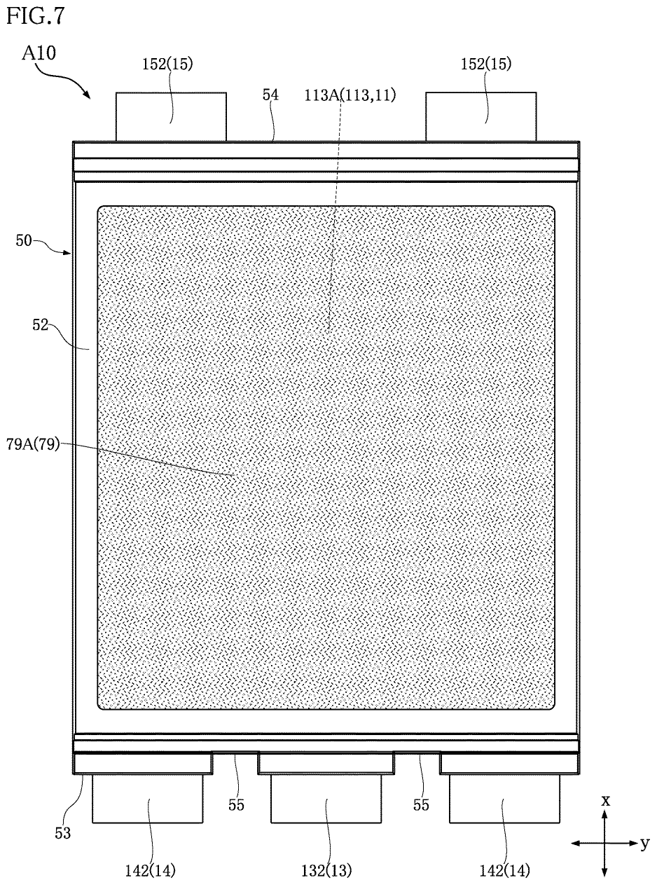

As shown in FIGS. 8 and 9, the top surface 51 faces the same side as the first obverse surface 121A of the first conductive layer 121 in the first direction z. As shown in FIGS. 8 and 9, the bottom surface 52 faces away from the top surface 51 in the first direction z. As shown in FIG. 7, the heat dissipation surface 113A of the heat dissipation layer 113 of the base material 11 is exposed from the bottom surface 52.

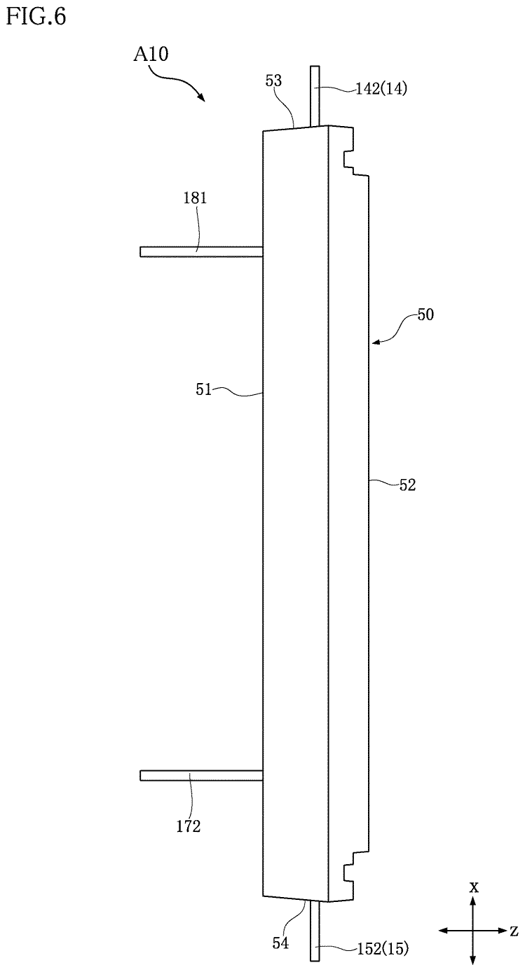

As shown in FIGS. 2 and 6, the first side surface 53 and the second side surface 54 are spaced apart from each other in the second direction x. The first side surface 53 and the second side surface 54 face away from each other in the second direction x. The exposed portion 132 of the first power terminal 13 and the exposed portion 142 of each of the two second power terminals 14 are exposed to the outside from the first side surface 53. The exposed portion 152 of each of the two third power terminals 15 is exposed to the outside from the second side surface 54.

As shown in FIGS. 2 and 7, the two recesses 55 are recessed from the first side surface 53 in the second direction x. The two recesses 55 extend from the top surface 51 to the bottom surface 52 in the first direction z. The two recesses 55 are located on opposite sides with respect to the first power terminal 13 in the third direction y.

As shown in FIGS. 8 to 13, the bonding material 79 is located on a side opposite to the first conductive layer 121 and the second conductive layer 122 with respect to the base material 11 in the first direction z. The bonding material 79 is disposed on the heat dissipation surface 113A of the heat dissipation layer 113 of the base material 11. The bonding material 79 includes metal particles. The metal particles include silver. Alternatively, the metal particles may include copper. The bonding material 79 is a dried product of a paste containing the metal particles and a solvent. Alternatively, the bonding material 79 may be a sheet containing the metal particles and a binder.

As shown in FIGS. 10 and 11, the bonding material 79 is in contact with the heat dissipation surface 113A of the heat dissipation layer 113. As shown in FIG. 7, as viewed in the first direction z, the bonding material 79 overlaps with an entirety of the heat dissipation surface 113A.

As shown in FIG. 14, the bonding material 79 includes a bonding surface 79A facing the same side as the heat dissipation surface 113A of the heat dissipation layer 113 in the first direction z. The bonding surface 79A has a surface roughness smaller than a surface roughness of the heat dissipation surface 113A.

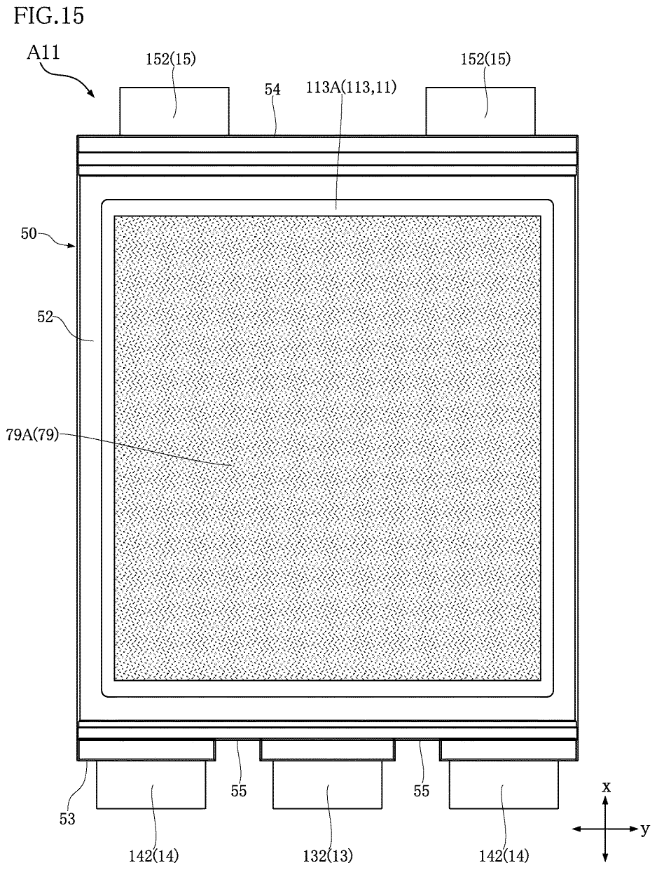

Next, a semiconductor device A11 according to a variation of the first embodiment of the present disclosure will be described with reference to FIG. 15. FIG. 15 corresponds to FIG. 7 showing the semiconductor device A10. The semiconductor device A11 differs from the semiconductor device A10 in a configuration of the bonding material 79.

As shown in FIG. 15, as viewed in the first direction z, the bonding material 79 is located inward of a peripheral edge of the heat dissipation surface 113A of the heat dissipation layer 113 of the base material 11.

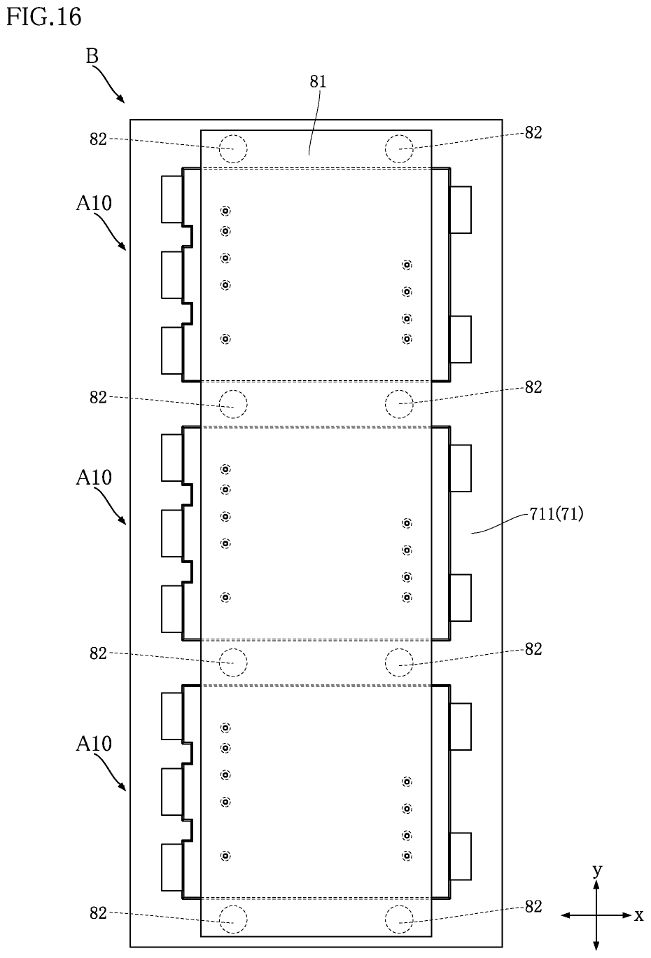

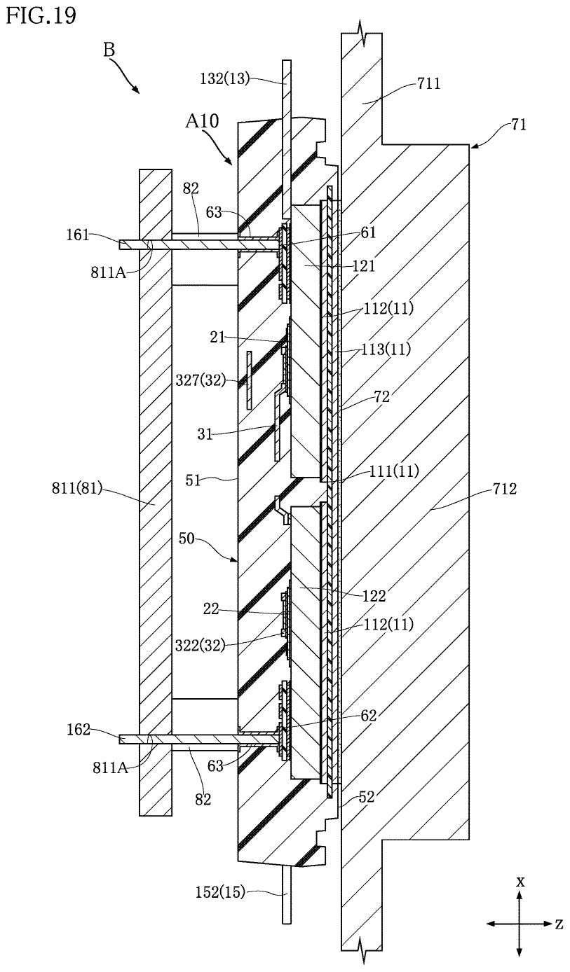

Next, an inverter device B including the semiconductor device A10 will be described with reference to FIGS. 16 to 23. Here, FIG. 19 corresponds to FIG. 9 showing the semiconductor device A10. The inverter device B includes three semiconductor devices A10, a heat sink 71, a wiring board 81, and a plurality of support members 82. The inverter device B further includes a bonding layer 72 in place of the bonding material 79 for each of the three semiconductor devices A10. The inverter device B is used to drive a motor 89 described later.

A configuration of the inverter device B will be described with reference to FIGS. to 20. The heat sink 71 serves to cool the inverter device B. The heat sink 71 contains metal. The heat sink 71 is made of, for example, a material containing aluminum (Al).

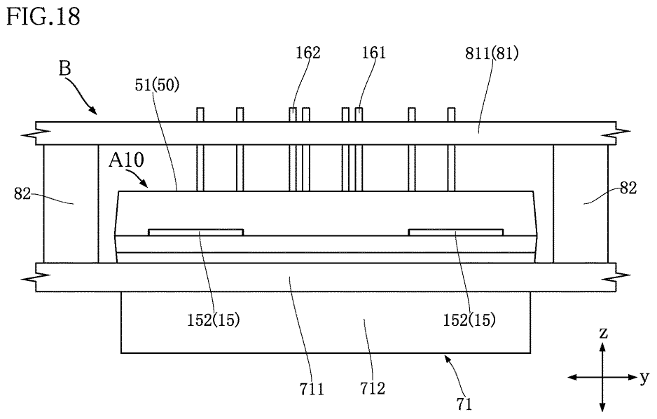

As shown in FIGS. 18 and 19, the heat sink 71 includes a base portion 711 and a heat radiating portion 712. The base portion 711 has a flat plate shape. The base portion 711 faces the heat dissipation layer 113 of the base material 11 of each of the three semiconductor devices A10 in the first direction z. As shown in FIG. 16, the three semiconductor devices A10 are arranged along the third direction y on the base portion 711. The heat radiating portion 712 is connected to the base portion 711. The heat radiating portion 712 is located on a side opposite to the base material 11 of each of the three semiconductor devices A10 with respect to the base portion 711 in the first direction z. The heat radiating portion 712 projects from the base portion 711. In the inverter device B, the heat radiating portion 712 has a cuboid shape. Alternatively, the heat radiating portion 712 may include fins arranged in a direction orthogonal to the first direction z.

As shown in FIG. 19, the bonding layer 72 bonds the base portion 711 of the heat sink 71 and the heat dissipation layer 113 of the base material 11 of each of the three semiconductor devices A10. The bonding layer 72 contains a sintered body of metal particles. The metal particles include silver. Alternatively, the metal particles may include copper. The bonding layer 72 is formed by sintering the bonding material 79 of each of the three semiconductor devices A10 (see a fourth step S4 described later).

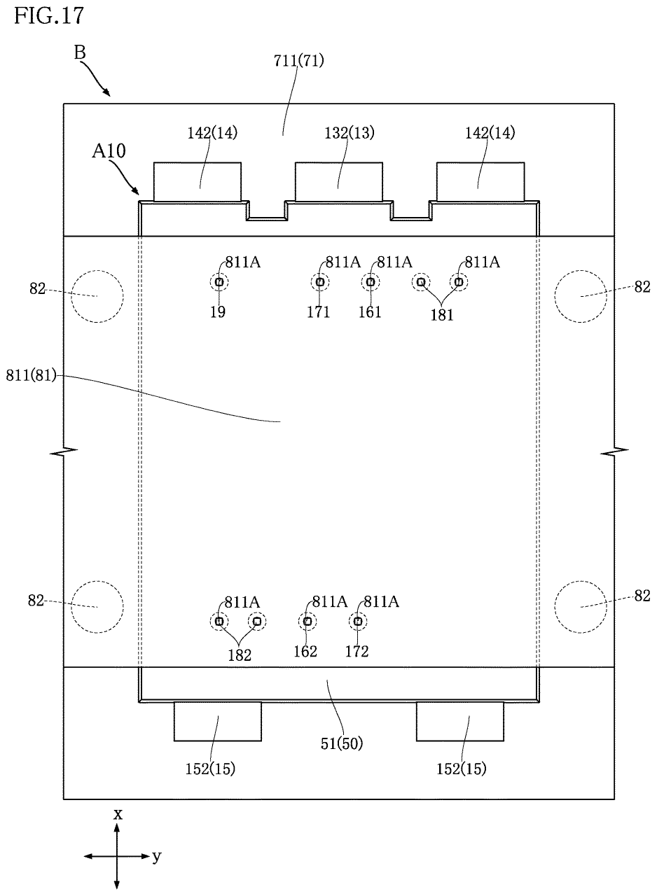

The wiring board 81 is electrically connected to the first signal terminal 161, the second signal terminal 162, the third signal terminal 171, the fourth signal terminal 172, the two fifth signal terminals 181, the two sixth signal terminals 182, and the seventh signal terminal 19 of each of the three semiconductor devices A10. As shown in FIGS. 17 to 19, the wiring board 81 faces the top surface 51 of the sealing resin 50 of each of the three semiconductor devices A10.

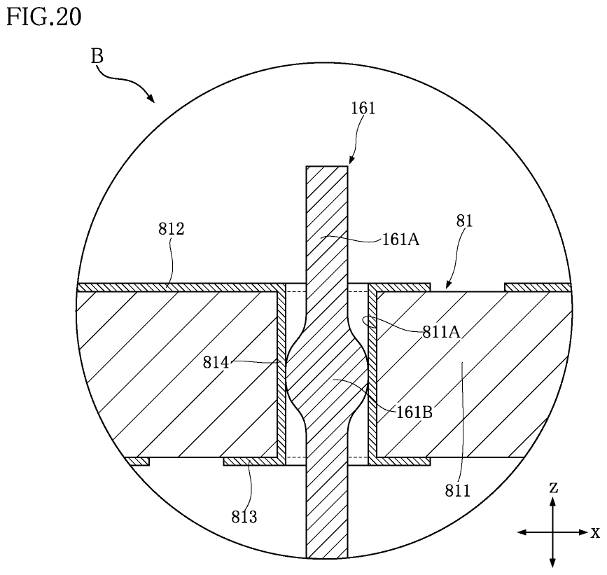

As shown in FIG. 20, the wiring board 81 includes a substrate 811, an obverse wiring 812, a reverse wiring 813, and an internal wiring 814. The substrate 811 is provided with a plurality of through holes 811A extending through the substrate 811 in the first direction z. The obverse wiring 812 is disposed on a side opposite to the sealing resin 50 of each of the three semiconductor devices A10 with respect to the substrate 811 in the first direction z. The reverse wiring 813 is disposed on a side opposite to the obverse wiring 812 with respect to the substrate 811. The internal wiring 814 is disposed at the through holes 811A. The internal wiring 814 is connected to the obverse wiring 812 and the reverse wiring 813. The obverse wiring 812 forms a conductive path between the internal wiring 814 and a control circuit 83 and a plurality of drive circuits 84 provided in the wiring board 81. Details of the control circuit 83 and the drive circuits 84 will be described later.

As shown in FIG. 20, the first signal terminal 161 of each of the three semiconductor devices A10 includes a base portion 161A and a bulging portion 161B. A first side in the first direction z of the base portion 161A is press-fitted into one of the sleeves 63 of each of the three semiconductor devices A10. The bulging portion 161B is provided on a second side in the first direction z of the base portion 161A. The bulging portion 161B bulges in a direction orthogonal to the first direction z.

As shown in FIGS. 17 and 19, the first signal terminal 161 of each of the three semiconductor devices A10 is press-fitted into one of the through holes 811A. As a result, as shown in FIG. 20, the bulging portion 161B of the first signal terminal 161 is pressed against the internal wiring 814 disposed in the corresponding one of the through holes 811A. Hence, the first signal terminal 161 is electrically connected to the wiring board 81. The second signal terminal 162, the third signal terminal 171, the fourth signal terminal 172, the two fifth signal terminals 181, the two sixth signal terminals 182, and the seventh signal terminal 19 of each of the three semiconductor devices A10 also have configurations similar to the base portion 161A and the bulging portion 161B of the first signal terminal 161. Hence, these signal terminals are press-fitted into the respective through holes 811A, thereby being electrically connected to the wiring board 81. With such a configuration, the inverter device B may be made more compact.

As shown in FIG. 18, the support members 82 are located between the base portion 711 of the heat sink 71 and the wiring board 81 in the first direction z. The wiring board 81 is supported by the support members 82. The support members 82 each have a columnar shape.

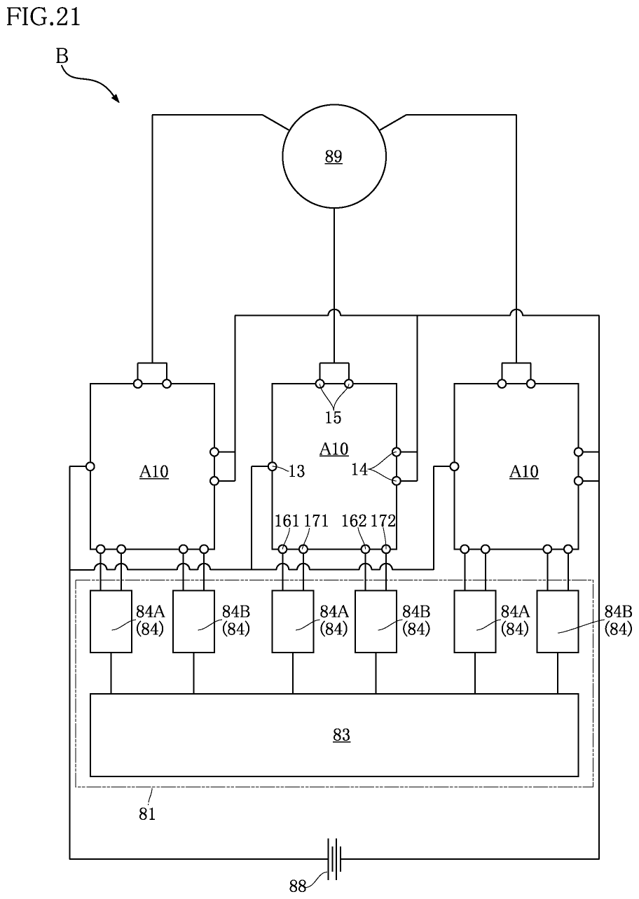

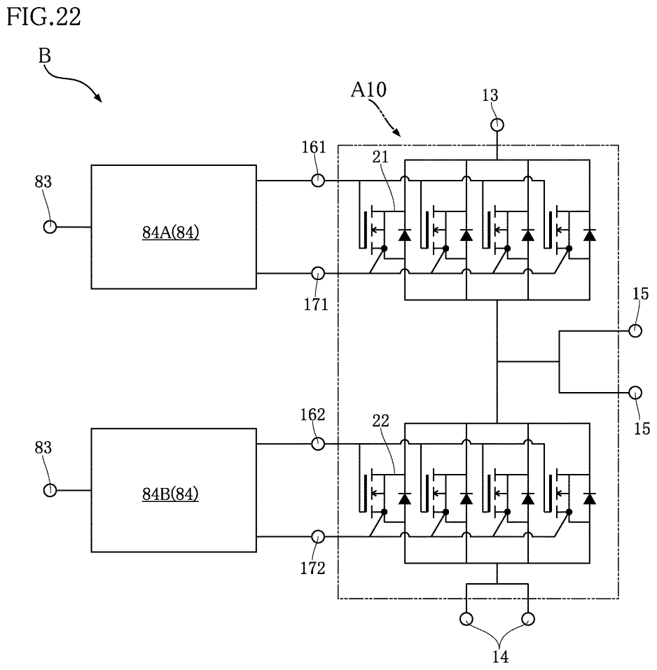

Next, a circuit of the inverter device B will be described with reference to FIGS. 21 and 22. The wiring board 81 is provided with a control circuit 83 and a plurality of drive circuits 84 electrically connected to the obverse wiring 812. The control circuit 83 is a microcomputer including a CPU (Central Processing Unit) and a memory. The control circuit 83 is electrically connected to the drive circuits 84 and is connected to the outside. The control circuit 83 generates control signals for driving the drive circuits 84 in response to input signals from the outside. The control signals are generated based on, for example, PWM (Pulse Width Modulation) control. The generated control signals are individually output to the drive circuits 84.

Each drive circuit 84 generates a drive signal for driving one of the three semiconductor devices A10 in response to the corresponding control signal input from the control circuit 83. The generated drive signal is output to the first signal terminal 161 or the second signal terminal 162 of the corresponding one of the three semiconductor devices A10.

As shown in FIG. 21, the drive circuits 84 include three first drive circuits 84A and three second drive circuits 84B. As shown in FIG. 22, each of the three first drive circuits 84A drives the first semiconductor elements 21 of the corresponding one of the three semiconductor devices A10. Each of the three first drive circuits 84A is electrically connected to the first signal terminal 161 and the third signal terminal 171 of the corresponding one of the three semiconductor devices A10. As shown in FIG. 22, each of the three second drive circuits 84B drives the second semiconductor elements 22 of the corresponding one of the three semiconductor devices A10. Each of the three second drive circuits 84B is electrically connected to the second signal terminal 162 and the fourth signal terminal 172 of the corresponding one of the three semiconductor devices A10.

As shown in FIG. 21, the first power terminal 13 of each of the three semiconductor devices A10 is electrically connected to a positive electrode of a DC power supply 88. The two second power terminals 14 of each of the three semiconductor devices A10 are electrically connected to a negative electrode of the DC power supply 88. Accordingly, DC power is input to each of the three semiconductor devices A10. Then, the drive circuits 84 drive the first semiconductor elements 21 and the second semiconductor elements 22 of each of the three semiconductor devices A10, so that AC power corresponding to a U-phase, a V-phase, or a W-phase is output from the two third power terminals 15 of each of the three semiconductor devices A10, thereby providing three-phase AC power.

As shown in FIG. 21, a motor 89 is electrically connected to the two third power terminals 15 of each of the three semiconductor devices A10. The motor 89 is a three-phase induction motor. The three-phase AC power output from the two third power terminals 15 of each of the three semiconductor devices A10 is input to the motor 89. Hence, the motor 89 is driven.

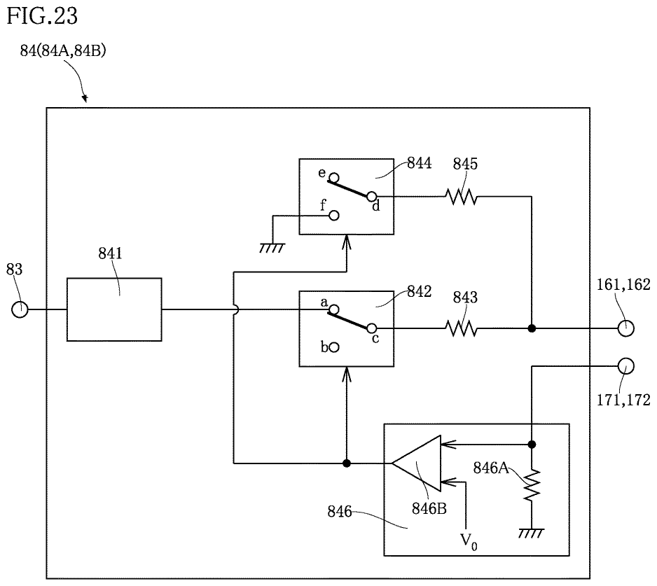

Next, a circuit of each drive circuit 84 will be described with reference to FIG. 23. Each drive circuit 84 includes an amplifier circuit 841, a first switch circuit 842, a gate resistor 843, a second switch circuit 844, a current interruption resistor 845, and an overcurrent detection circuit 846.

The amplifier circuit 841 receives the control signal from the control circuit 83. The amplifier circuit 841 amplifies the control signal and generates a drive signal for driving one of the three semiconductor devices A10. The first switch circuit 842 includes terminals a, b, and c. The terminals a and b are input-side terminals. The terminal c is an output-side terminal. In the first switch circuit 842, the terminal c is connected to either the terminal a or the terminal b. The terminal a is connected to the amplifier circuit 841. The terminal b is electrically open. The terminal c is electrically connected, through the gate resistor 843, to the first signal terminal 161 or the second signal terminal 162 of the corresponding one of the three semiconductor devices A10.

The second switch circuit 844 includes terminals d, e, and f. The terminal d is an input-side terminal. The terminals e and f are output-side terminals. In the second switch circuit 844, the terminal d is connected to either the terminal e or the terminal f. The terminal d is electrically connected, through the current interruption resistor 845, to the first signal terminal 161 or the second signal terminal 162 of the corresponding one of the three semiconductor devices A10. In each drive circuit 84, the gate resistor 843 and the current interruption resistor 845 are connected in parallel to each other relative to the first signal terminal 161 or the second signal terminal 162 of the corresponding one of the three semiconductor devices A10. The terminal e is electrically open. The terminal f is grounded. The current interruption resistor 845 has a resistance value r2 greater than a resistance value r1 of the gate resistor 843.

The overcurrent detection circuit 846 controls the first switch circuit 842 and the second switch circuit 844. The overcurrent detection circuit 846 includes a current detection resistor 846A and a comparison circuit 846B. One end of the current detection resistor 846A is electrically connected to the third signal terminal 171 or the fourth signal terminal 172 of the corresponding one of the three semiconductor devices A10. The other end of the current detection resistor 846A is grounded. The voltage across the current detection resistor 846A (voltage drop amount) corresponds to a drain-source voltage of each first semiconductor element 21 of the corresponding one of the three semiconductor devices A10, or to a drain-source voltage of each second semiconductor element 22 of the corresponding one of the three semiconductor devices A10. The voltage across the current detection resistor 846A is applied to the comparison circuit 846B. The comparison circuit 846B determines whether the first semiconductor elements 21 or the second semiconductor elements 22 of the corresponding one of the three semiconductor devices A10 are in an overcurrent state by comparing the voltage across the current detection resistor 846A with a reference voltage V₀. The comparison circuit 846B outputs a determination signal indicating the determined result. Specifically, when the voltage across the current detection resistor 846A is greater than the reference voltage V₀, the comparison circuit 846B determines that the overcurrent state is present.

When the overcurrent state is not present (during normal operation), the terminal d is connected to the terminal e in the second switch circuit 844. At this time, the impedance of the terminal d of the second switch circuit 844 is sufficiently high. In addition, the terminal c is connected to the terminal a in the first switch circuit 842. Hence, the drive signal generated by the amplifier circuit 841 is output, through the gate resistor 843, to the first signal terminal 161 or the second signal terminal 162 of the corresponding one of the three semiconductor devices A10.

When the overcurrent state is present, the terminal c is connected to the terminal b in the first switch circuit 842. At this time, the impedance of the terminal c of the first switch circuit 842 is sufficiently high. In addition, the terminal d is connected to the terminal f in the second switch circuit 844. Hence, the terminal d is grounded.

Therefore, when the overcurrent state is present, the first signal terminal 161 or the second signal terminal 162 of the corresponding one of the three semiconductor devices A10 is grounded through the current interruption resistor 845. This reduces the gate-source voltage of each first semiconductor element 21 or the gate-source voltage of each second semiconductor element 22 of the corresponding one of the three semiconductor devices A10. Further, a short-circuit current between the drain and the source of each first semiconductor element 21 (hereinafter referred to as a “short-circuit current”), or a short-circuit current of each second semiconductor element 22 of the corresponding one of the three semiconductor devices A10, is interrupted. With this operation, the drive circuits 84 serve to protect the first semiconductor elements 21 and the second semiconductor elements 22 from overcurrent. The interruption speed of the short-circuit current varies depending on the resistance value r2 of the current interruption resistor 845. As the resistance value r2 increases, the interruption speed of the short-circuit current decreases.

Here, when a short-circuit current exceeds the short-circuit withstand capability of any first semiconductor element 21 or any second semiconductor element 22, the relevant first semiconductor element 21 or second semiconductor element 22 may be destroyed before overcurrent protection by the drive circuits 84 is completed. In view of this, an internal resistor may be provided between the second electrode 212 and the first detection electrode 214 inside each first semiconductor element 21, for example. The internal resistor reduces the gate-source voltage when the short-circuit current flows, thereby more reliably preventing the relevant first semiconductor element 21 or second semiconductor element 22 from being destroyed.

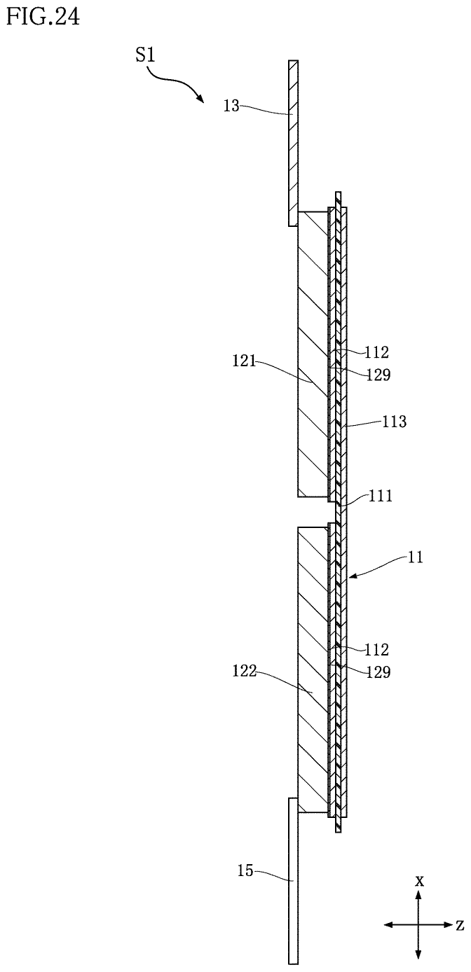

Next, an example of a method for manufacturing the inverter device B will be described with reference to FIGS. 24 to 29. In the description of the inverter device B, one of the three semiconductor devices A10 is described as a representative example. FIGS. 24 to 29 correspond to FIG. 9 showing the semiconductor device A10.

First, a first step S1 shown in FIG. 24 is performed. The first step S1 includes bonding the first conductive layer 121 and the second conductive layer 122 to the base material 11 including the heat dissipation layer 113 such that the first conductive layer 121 and the second conductive layer 122 are located on a side opposite to the heat dissipation layer 113 in the first direction z. The first conductive layer 121 and the second conductive layer 122 are individually bonded to the two support layers 112 of the base material 11 by the respective first bonding layers 129. Further, the first step S1 includes conductively bonding the first power terminal 13 to the first conductive layer 121 by laser welding. The first step S1 also includes conductively bonding the two third power terminals 15 to the second conductive layer 122 by laser welding.

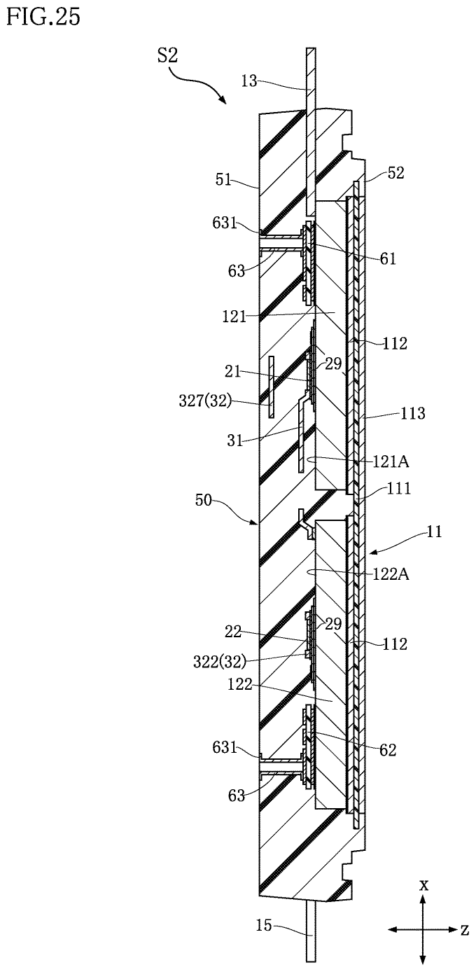

Next, a second step S2 shown in FIG. 25 is performed. The second step S2 includes conductively bonding the first semiconductor elements 21 to the first conductive layer 121 by conductive bonding layers 29, respectively. The second step S2 also includes conductively bonding the second semiconductor elements 22 to the second conductive layer 122 by conductive bonding layers 29, respectively. Thereafter, the first conductive member 31 is conductively bonded to the first semiconductor elements 21 and the second conductive layer 122. Next, the two second power terminals 14 are disposed, and the second conductive member 32 is conductively bonded to the second semiconductor elements 22 and the two second power terminals 14. Subsequently, the first wiring 61 is bonded to the first conductive layer 121. In addition, the second wiring 62 is bonded to the second conductive layer 122. The sealing resin 50 covering the first conductive layer 121, the second conductive layer 122, the first semiconductor elements 21, the second semiconductor elements 22, the first conductive member 31, and the second conductive member 32 is then formed. The sealing resin 50 is formed by transfer molding. In forming the sealing resin 50, the heat dissipation surface 113A of the heat dissipation layer 113 of the base material 11 and the end surface 631 of each of the sleeves 63 are exposed from the sealing resin 50.

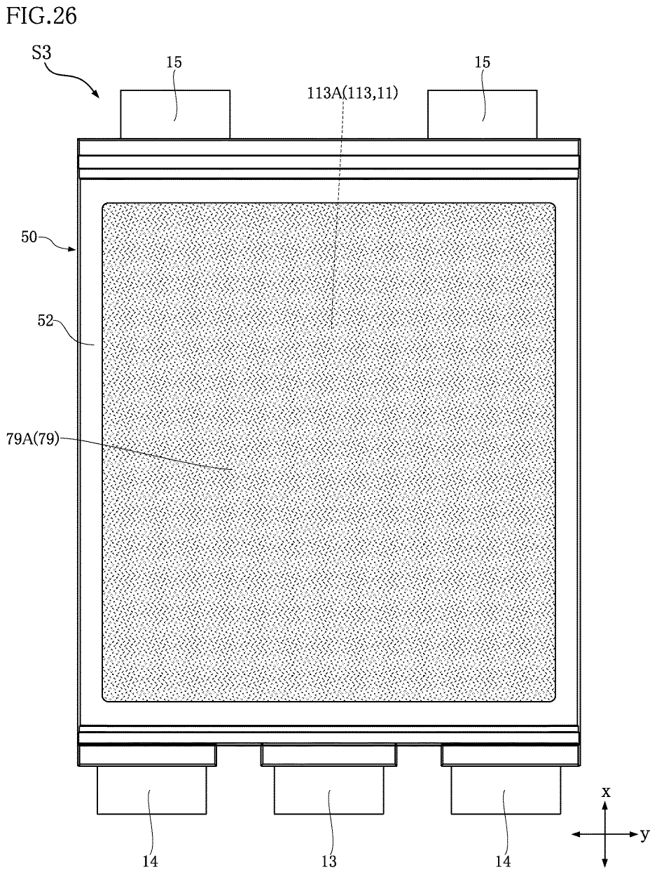

Next, a third step S3 shown in FIG. 26 is performed. The third step S3 includes disposing the bonding material 79 on the heat dissipation layer 113 of the base material 11 on the first side in the first direction z. The bonding material 79 is brought into contact with the heat dissipation surface 113A of the heat dissipation layer 113. The bonding material 79 includes metal particles. The metal particles include silver. The bonding material 79 is a paste containing the metal particles and a solvent. The bonding material 79 is disposed on the heat dissipation surface 113A by a dispenser or screen printing. Thereafter, the bonding material 79 is dried to remove the solvent contained in the bonding material 79. Alternatively, the bonding material 79 may be a sheet containing the metal particles. In this case, the sheet is attached to the heat dissipation surface 113A. In the third step S3, the bonding material 79 is, as shown in FIG. 14, provided such that a surface roughness of the bonding surface 79A of the bonding material 79 is smaller than a surface roughness of the heat dissipation surface 113A.

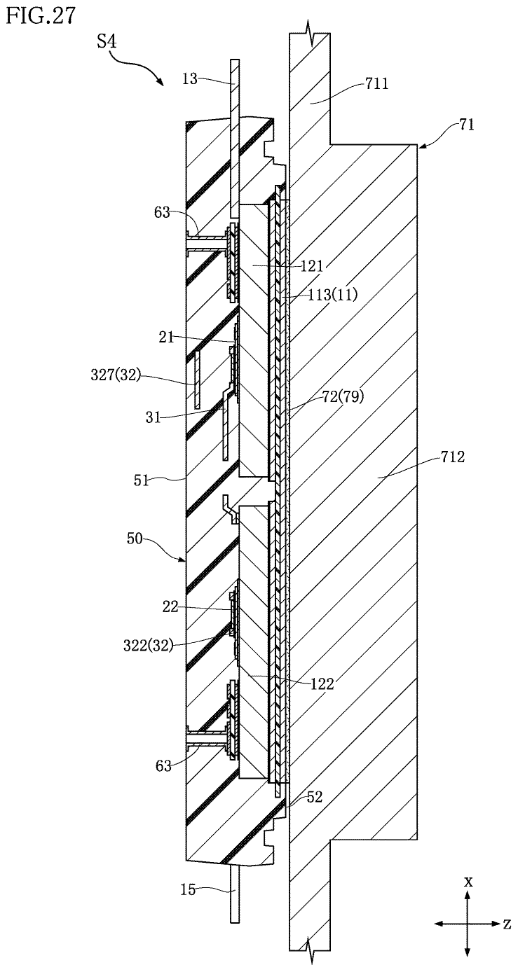

Next, a fourth step S4 shown in FIG. 27 is performed. The fourth step S4 includes sintering the bonding material 79 to bond the heat sink 71 and the heat dissipation layer 113 of the base material 11. At this time, the bonding surface 79A of the bonding material 79 is in contact with the base portion 711 of the heat sink 71. The bonding material 79 sintered in the fourth step S4 forms the bonding layer 72.

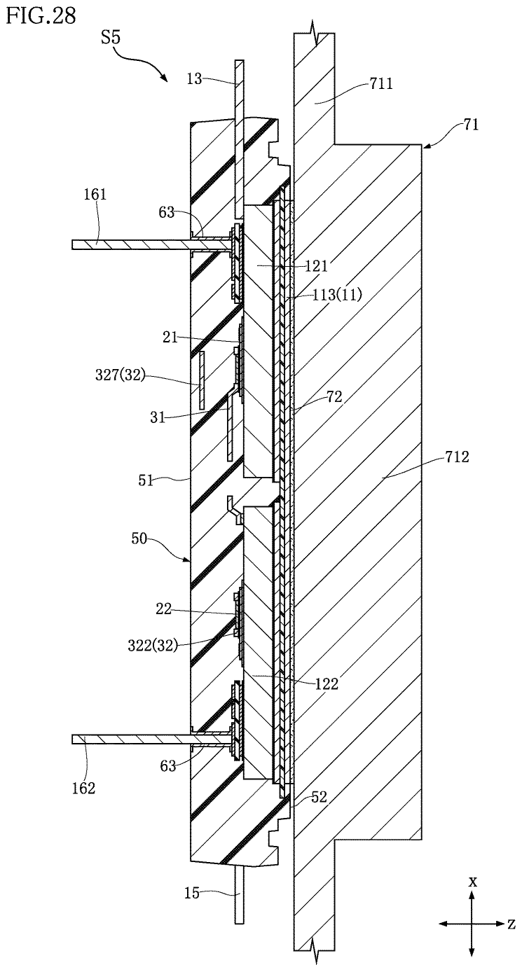

Next, a fifth step S5 shown in FIG. 28 is performed. The fifth step S5 includes press fitting the first signal terminal 161, the second signal terminal 162, the third signal terminal 171, the fourth signal terminal 172, the two fifth signal terminals 181, the two sixth signal terminals 182, and the seventh signal terminal 19 into the sleeves 63, respectively. Accordingly, the first signal terminal 161 electrically connected to the first gate electrode 213 of each first semiconductor element 21 and the second signal terminal 162 electrically connected to the second gate electrode 223 of each second semiconductor element 22 are disposed.

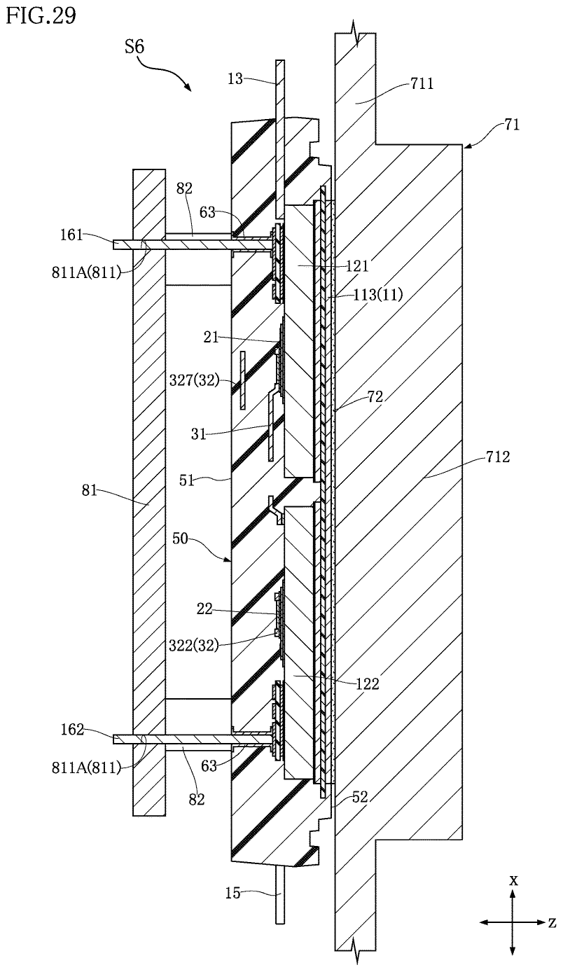

Finally, a sixth step S6 shown in FIG. 29 is performed. The sixth step S6 includes press-fitting the first signal terminal 161, the second signal terminal 162, the third signal terminal 171, the fourth signal terminal 172, the two fifth signal terminals 181, the two sixth signal terminals 182, and the seventh signal terminal 19 into the through holes 811A of the substrate 811 of the wiring board 81, respectively. The sixth step S6 also includes disposing the support members 82 on the base portion 711 of the heat sink 71 such that the wiring board 81 is supported by the support members 82. Accordingly, the wiring board 81 electrically connected to the first signal terminal 161 and the second signal terminal 162 is disposed. Through the steps described above, the inverter device B is obtained.

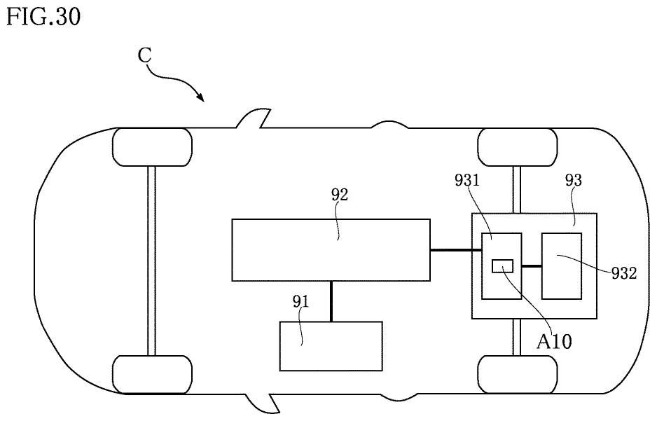

Next, a vehicle C on which the semiconductor device A10 is installed will be described with reference to FIG. 30. The vehicle C is, for example, an electric vehicle (EV).

As shown in FIG. 30, the vehicle C includes an on-board charger 91, a storage battery 92, and a drive system 93. The on-board charger 91 receives power wirelessly from an outdoor power supply facility (not shown). Alternatively, the on-board charger 91 may receive power from the power supply facility by wire. The on-board charger 91 includes a step-up DC-DC converter. The voltage of the power supplied to the on-board charger 91 is boosted by the converter and then supplied to the storage battery 92. The voltage is boosted to 600 V, for example.

The drive system 93 drives the vehicle C. The drive system 93 includes an inverter 931 and a drive source 932. The semiconductor device A10 constitutes a part of the inverter 931. Alternatively, the inverter 931 may include a plurality of the above-described inverter devices B. The power stored in the storage battery 92 is supplied to the inverter 931. The power supplied from the storage battery 92 to the inverter 931 is DC power. In an example different from FIG. 30, the power system may additionally include a step-up DC-DC converter between the storage battery 92 and the inverter 931. The inverter 931 converts the DC power into AC power. The inverter 931 that includes the semiconductor device A10 is electrically connected to the drive source 932. The drive source 932 includes an AC motor and a transmission. The AC power converted by the inverter 931 is supplied to the drive source 932 to rotate the AC motor. The rotation of the AC motor is transmitted to the transmission. The transmission appropriately reduces the rotational speed transmitted from the AC motor and rotates the drive shaft of the vehicle C. This drives the vehicle C. Driving the vehicle C requires freely regulating the rotational speed of the AC motor based on the amount of accelerator pedal operation and other information. The semiconductor device A10 in the inverter 931 is necessary for outputting the AC power at a frequency appropriately adjusted to correspond to the required rotational speed of the AC motor.

Next, effects of the semiconductor device A10 will be described.

The semiconductor device A10 includes a base material 11 including a heat dissipation layer 113, a first conductive layer 121, a first semiconductor element 21, and a bonding material 79. The bonding material 79 is located on a side opposite to the first conductive layer 121 with respect to the base material 11 in the first direction z, and is disposed on the heat dissipation layer 113. The bonding material 79 includes metal particles. With such a configuration, the pre-formed bonding material 79 is provided in advance on the heat dissipation layer 113, thereby making it possible to avoid occurrence of a defect or other failure in the bonding material 79. Thus, in the fourth step S4 among the manufacturing steps of the inverter device B, when the heat sink 71 and the heat dissipation layer 113 are bonded by sintering the bonding material 79, a bonded state between the heat sink 71 and the heat dissipation layer 113 is improved. Accordingly, with respect to the semiconductor device A10, such a configuration can suppress peeling of the base material 11 from the heat sink 71 when the heat sink 71 and the base material 11 are bonded.

The bonding material 79 includes a bonding surface 79A facing the same side as a heat dissipation surface 113A of the heat dissipation layer 113 in the first direction z. The bonding surface 79A has a surface roughness smaller than a surface roughness of the heat dissipation surface 113A. With such a configuration, the inverter device B may be advantageous for further improving the bonded state between the heat sink 71 and the heat dissipation layer 113.

In the semiconductor device A11, as viewed in the first direction z, the bonding material 79 is located inward of a peripheral edge of the heat dissipation surface 113A of the heat dissipation layer 113. Thus, in the inverter device B, a gap is formed between a corner portion of the heat dissipation layer 113 and the heat sink 71 in the first direction z. In manufacturing the inverter device B, shear stress caused by heat generated in sintering the bonding material 79 occurs at an interface between the bonding layer 72 and the heat dissipation layer 113. The shear stress tends to concentrate at the corner portion of the heat dissipation layer 113. Thus, such a configuration can reduce the shear stress transmitted from the corner portion of the heat dissipation layer 113 to the bonding layer 72, thereby making it possible to effectively suppress peeling of the base material 11 from the heat sink 71.

### Second Embodiment

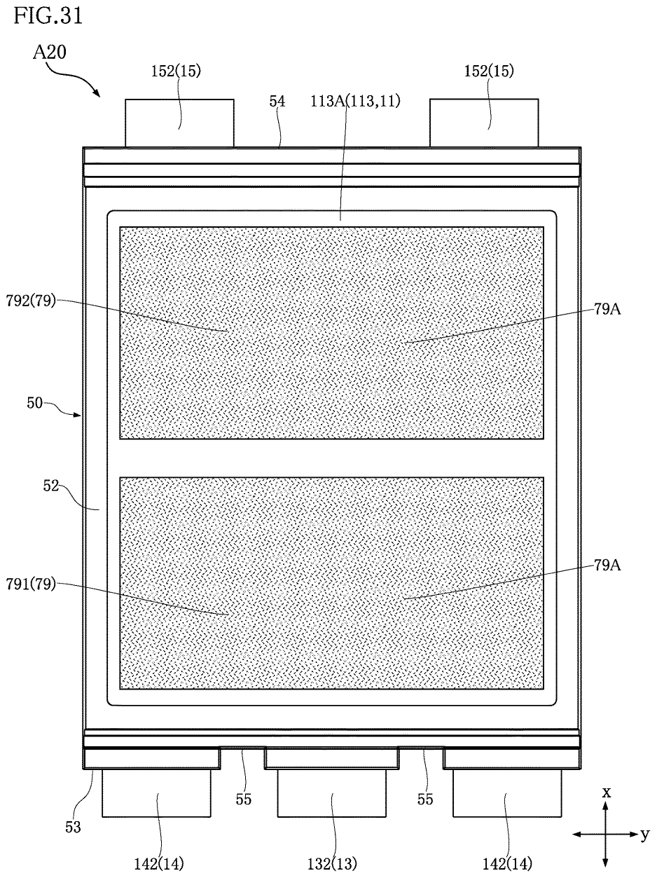

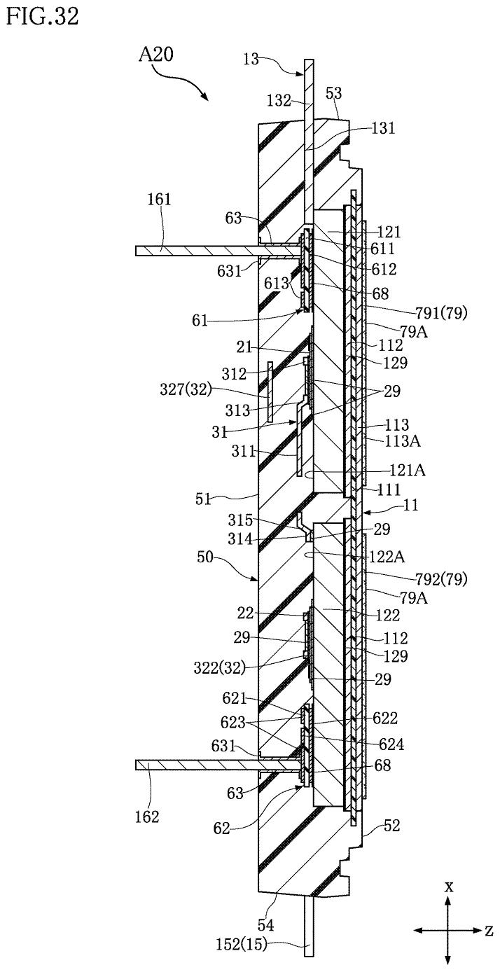

A semiconductor device A20 according to a second embodiment of the present disclosure will be described with reference to FIGS. 31 and 32. Elements identical or similar to those of the semiconductor device A10 described above are marked with the same numerals in these figures, and redundant descriptions are omitted. FIG. 31 corresponds to FIG. 7 showing the semiconductor device A10. FIG. 32 corresponds to FIG. 9 showing the semiconductor device A10.

The semiconductor device A20 differs from the semiconductor device A10 in a configuration of the bonding material 79.

As shown in FIGS. 31 and 32, the bonding material 79 includes a first portion 791 and a second portion 792 spaced apart from each other in the second direction x. As viewed in the first direction z, the first semiconductor elements 21 overlap with the first portion 791. As viewed in the first direction z, the second semiconductor elements 22 overlap with the second portion 792.

Next, effects of the semiconductor device A20 will be described.

The semiconductor device A20 includes a base material 11 including a heat dissipation layer 113, a first conductive layer 121, a first semiconductor element 21, and a bonding material 79. The bonding material 79 is located on a side opposite to the first conductive layer 121 with respect to the base material 11 in the first direction z, and is disposed on the heat dissipation layer 113. The bonding material 79 includes metal particles. Accordingly, the semiconductor device A20 may also be advantageous for suppressing peeling of the base material 11 from the heat sink 71 when the heat sink 71 and the base material 11 are bonded. In addition, the semiconductor device A20 may have a configuration in common with the semiconductor device A10, thereby achieving the same effects as the semiconductor device A10.

In the semiconductor device A20, the bonding material 79 includes the first portion 791 and the second portion 792 spaced apart from each other in the second direction x. With such a configuration, it is possible to further disperse a distribution of shear stress occurring at an interface between the bonding layer 72 and the heat dissipation layer 113 due to heat generated in sintering the bonding material 79.

In the above case, as viewed in the first direction z, the first semiconductor element 21 overlaps with the first portion 791. With such a configuration, when the inverter device B is used, heat generated from the first semiconductor element 21 can be smoothly conducted from the heat dissipation layer 113 to the heat sink 71 through the bonding layer 72.

### Third Embodiment

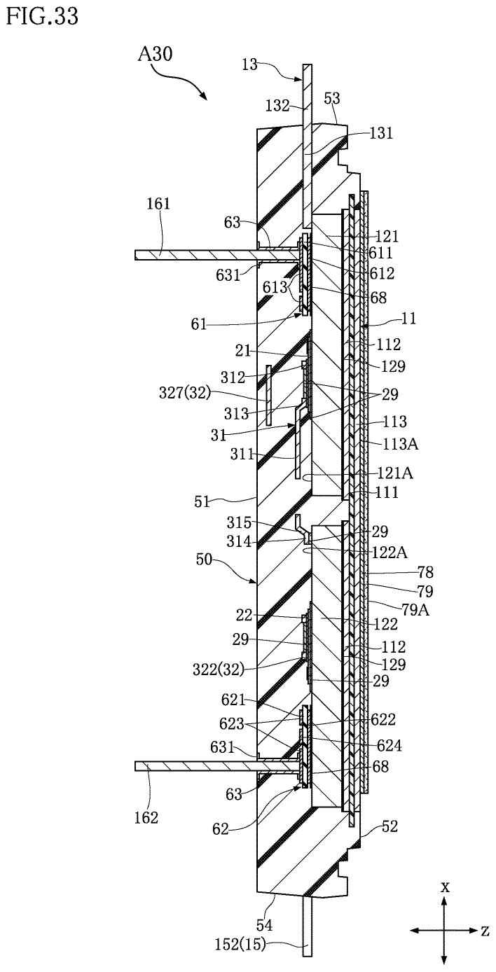

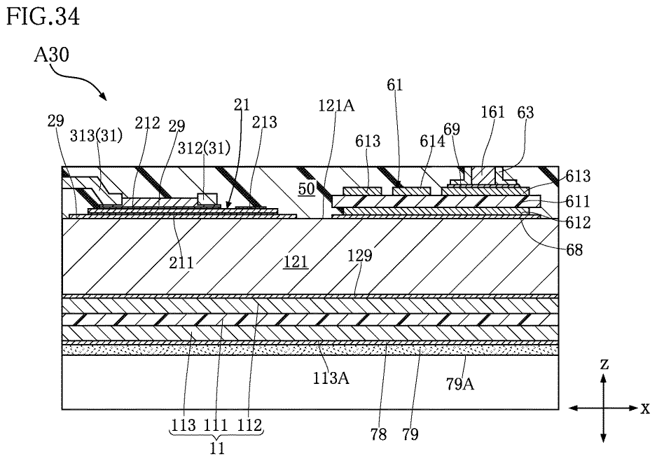

A semiconductor device A30 according to a third embodiment of the present disclosure will be described with reference to FIGS. 33 and 34. Elements identical or similar to those of the semiconductor device A10 described above are marked with the same numerals in these figures, and redundant descriptions are omitted. FIG. 33 corresponds to FIG. 9 showing the semiconductor device A10.

The semiconductor device A30 differs from the semiconductor device A10 in that the semiconductor device A30 further includes an intermediate layer 78.

As shown in FIGS. 33 and 34, the intermediate layer 78 is located between the heat dissipation surface 113A of the heat dissipation layer 113 of the base material 11 and the bonding material 79. The bonding material 79 is in contact with the intermediate layer 78. The intermediate layer 78 contains silver. Accordingly, the intermediate layer 78 and the metal particles in the bonding material 79 include the same metal element. Further, the metal element in the intermediate layer 78 is different from a metal element in the heat dissipation layer 113. The intermediate layer 78 is formed by, for example, electrolytic plating.

As shown in FIG. 34, the intermediate layer 78 is in contact with the heat dissipation surface 113A of the heat dissipation layer 113. The intermediate layer 78 has a dimension in the first direction z smaller than a dimension of the bonding material 79 in the first direction z.

Next, effects of the semiconductor device A30 will be described.

The semiconductor device A30 includes a base material 11 including a heat dissipation layer 113, a first conductive layer 121, a first semiconductor element 21, and a bonding material 79. The bonding material 79 is located on a side opposite to the first conductive layer 121 with respect to the base material 11 in the first direction z, and is disposed on the heat dissipation layer 113. The bonding material 79 includes metal particles. Accordingly, the semiconductor device A30 may also be advantageous for suppressing peeling of the base material 11 from the heat sink 71 when the heat sink 71 and the base material 11 are bonded. In addition, the semiconductor device A30 may have a configuration in common with the semiconductor device A10, thereby achieving the same effects as the semiconductor device A10.

The semiconductor device A30 further includes the intermediate layer 78 located between the heat dissipation surface 113A of the heat dissipation layer 113 and the bonding material 79. The bonding material 79 is in contact with the intermediate layer 78. The intermediate layer 78 and the metal particles in the bonding material 79 include the same metal element. With such a configuration, when the bonding material 79 is sintered, a bonded state between the intermediate layer 78 and the bonding layer 72 can be strengthened. Accordingly, in the inverter device B, even when the metal element in the heat dissipation layer 113 is different from the metal element of the metal particles in the bonding material 79, interfacial peeling between the bonding layer 72 and the heat dissipation layer 113 can be suppressed.

### Fourth Embodiment

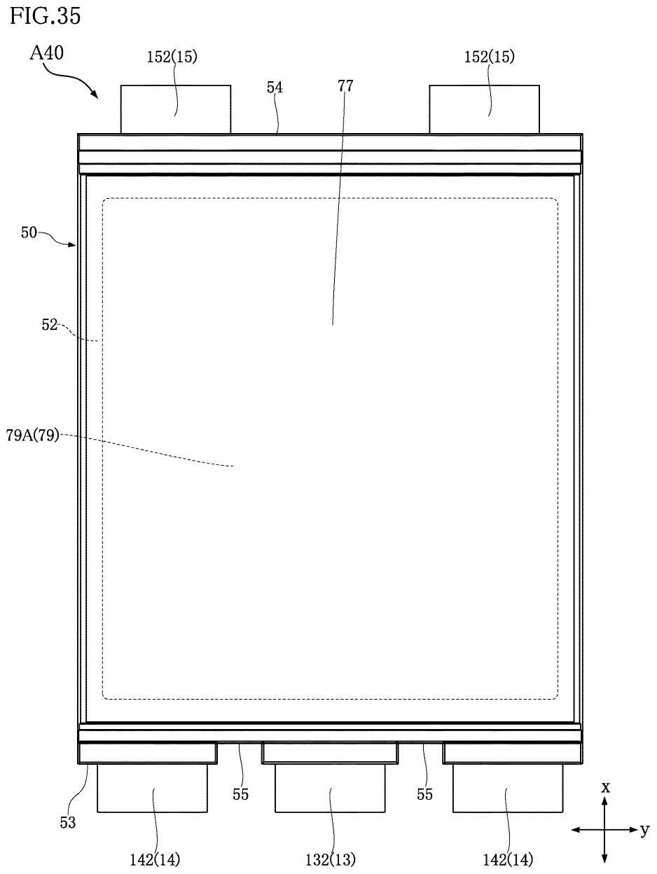

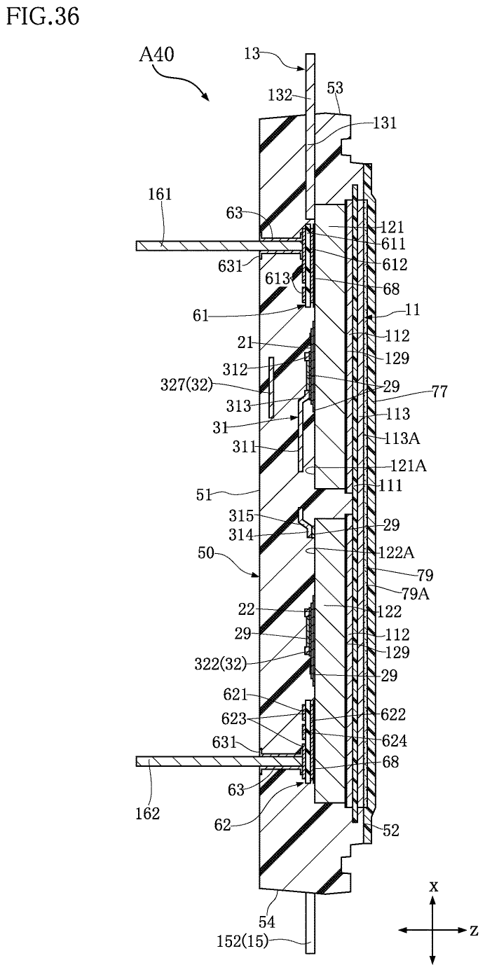

A semiconductor device A40 according to a fourth embodiment of the present disclosure will be described with reference to FIGS. 35 and 36. Elements identical or similar to those of the semiconductor device A10 described above are marked with the same numerals in these figures, and redundant descriptions are omitted. FIG. 35 corresponds to FIG. 7 showing the semiconductor device A10. FIG. 36 corresponds to FIG. 9 showing the semiconductor device A10.

The semiconductor device A40 differs from the semiconductor device A10 in that the semiconductor device A40 further includes a protective layer 77.

As shown in FIGS. 35 and 36, the protective layer 77 covers the bonding surface 79A of the bonding material 79. The protective layer 77 is an insulator. The protective layer 77 includes, for example, resin. The protective layer 77 is manually peelable from the bonding surface 79A. The protective layer 77 has sulfurization resistance. As viewed in the first direction z, the protective layer 77 extends outward beyond a peripheral edge of the bonding surface 79A. The protective layer 77 is in contact with the bottom surface 52 of the sealing resin 50.

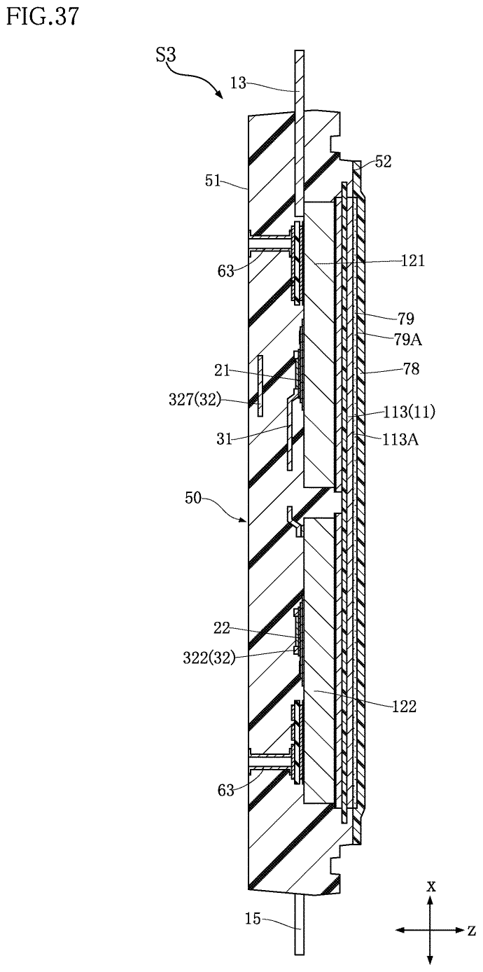

Next, an example of a method for manufacturing the inverter device B including the semiconductor device A40 in place of the semiconductor device A10 will be described with reference to FIG. 37. FIG. 37 corresponds to FIG. 9 showing the semiconductor device A10. In the present manufacturing method, the third step S3 described above differs.

As shown in FIG. 37, the third step S3 includes disposing the protective layer 77 covering the bonding material 79 after disposing the bonding material 79 on a first side in the first direction z of the heat dissipation layer 113 of the base material 11. Thereafter, the fourth step S4 includes removing the protective layer 77 by peeling before the bonding material 79 is sintered.

Next, effects of the semiconductor device A40 will be described.

The semiconductor device A40 includes a base material 11 including a heat dissipation layer 113, a first conductive layer 121, a first semiconductor element 21, and a bonding material 79. The bonding material 79 is located on a side opposite to the first conductive layer 121 with respect to the base material 11 in the first direction z, and is disposed on the heat dissipation layer 113. The bonding material 79 includes metal particles. Accordingly, the semiconductor device A40 may also be advantageous for suppressing peeling of the base material 11 from the heat sink 71 when the heat sink 71 and the base material 11 are bonded. In addition, the semiconductor device A40 may have a configuration in common with the semiconductor device A10, thereby achieving the same effects as the semiconductor device A10.

The semiconductor device A40 further includes the protective layer 77 covering the bonding surface 79A of the bonding material 79. With such a configuration, damage (e.g., abrasion) to the bonding material 79 disposed on the heat dissipation layer 113 can be more reliably prevented between the third step S3 and the fourth step S4 among the manufacturing steps of the inverter device B.

The present disclosure is not limited to the above-described embodiments. The specific configuration of each part of the present disclosure may be modified in various ways.

The present disclosure includes embodiments described in the following clauses.
Clause 1.

A semiconductor device comprising:
a base material including a heat dissipation layer;
a first conductive layer bonded to the base material;
a first semiconductor element bonded to the first conductive layer; and
a bonding material located on a side opposite to the first conductive layer with respect to the base material in a first direction, the bonding material being disposed on the heat dissipation layer,
wherein the bonding material includes metal particles.
Clause 2.

The semiconductor device according to clause 1, further comprising a sealing resin covering the first semiconductor element,
wherein the heat dissipation layer includes a heat dissipation surface exposed from the sealing resin, and
the bonding material is disposed on the heat dissipation surface.
Clause 3.

The semiconductor device according to clause 2, wherein the bonding material includes a bonding surface facing the same side as the heat dissipation surface in the first direction, and
the bonding surface has a surface roughness smaller than a surface roughness of the heat dissipation surface.
Clause 4.

The semiconductor device according to clause 3, further comprising a protective layer covering the bonding surface.
Clause 5.

The semiconductor device according to clause 4, wherein the protective layer is an insulator.
Clause 6.

The semiconductor device according to clause 5, wherein, as viewed in the first direction, the protective layer extends outward beyond a peripheral edge of the bonding surface.
Clause 7.

The semiconductor device according to clause 6, wherein the protective layer is in contact with the sealing resin.
Clause 8.

The semiconductor device according to clause 3, wherein, as viewed in the first direction, the bonding material overlaps with an entirety of the heat dissipation surface.
Clause 9.

The semiconductor device according to clause 3, wherein, as viewed in the first direction, the bonding material is located inward of a peripheral edge of the heat dissipation surface.
Clause 10.

The semiconductor device according to clause 3, further comprising an intermediate layer located between the heat dissipation surface and the bonding material,
wherein the bonding material is in contact with the intermediate layer, and
the intermediate layer includes the same metal element as the metal particles.
Clause 11.

The semiconductor device according to clause 10, wherein the intermediate layer is in contact with the heat dissipation surface, and
the intermediate layer includes a metal element different from a metal element included in the heat dissipation layer.
Clause 12.

The semiconductor device according to any one of clauses 3 to 11, wherein the base material includes an insulating layer located on a side opposite to the bonding material with respect to the heat dissipation layer, and
the first conductive layer is bonded to the insulating layer.
Clause 13.

The semiconductor device according to clause 12, further comprising:
a second conductive layer located on the same side as the first conductive layer with respect to the base material and bonded to the insulating layer; and
a second semiconductor element conductively bonded to the second conductive layer,
wherein the first semiconductor element is conductively bonded to the first conductive layer, and
the second semiconductor element is electrically connected to the first semiconductor element and is covered with the sealing resin.
Clause 14.

The semiconductor device according to clause 13, wherein the metal particles include silver.
Clause 15.

An inverter device comprising:
a heat sink;
a base material including a heat dissipation layer facing the heat sink in a first direction;
a first conductive layer and a second conductive layer located on a side opposite to the heat sink with respect to the base material and bonded to the base material;
a first semiconductor element conductively bonded to the first conductive layer;
a second semiconductor element conductively bonded to the second conductive layer;
a first signal terminal electrically connected to the first semiconductor element;
a second signal terminal electrically connected to the second semiconductor element;
a wiring board electrically connected to the first signal terminal and the second signal terminal; and
a bonding layer bonding the heat sink and the heat dissipation layer,
wherein the bonding layer includes a sintered body of metal particles.
Clause 16.

A method for manufacturing an inverter device, the method comprising:
a first step of bonding a first conductive layer and a second conductive layer to a base material including a heat dissipation layer such that the first conductive layer and the second conductive layer are located on a side opposite to the heat dissipation layer in a first direction;
a second step of conductively bonding a first semiconductor element to the first conductive layer and conductively bonding a second semiconductor element to the second conductive layer;
a third step of disposing a bonding material on the heat dissipation layer on a first side in the first direction;
a fourth step of sintering the bonding material to bond a heat sink and the heat dissipation layer;
a fifth step of disposing a first signal terminal electrically connected to the first semiconductor element and a second signal terminal electrically connected to the second semiconductor element; and
a sixth step of disposing a wiring board electrically connected to the first signal terminal and the second signal terminal,
wherein the bonding material includes metal particles.
Clause 17.

The method for manufacturing an inverter device according to clause 16, wherein the bonding material is a sheet including the metal particles, and
the third step includes attaching the sheet to the heat dissipation layer.
Clause 18.

The method for manufacturing an inverter device according to clause 16, wherein the bonding material is a paste including the metal particles, and
the third step includes applying the paste to the heat dissipation layer and then drying the paste.
Clause 19.

The method for manufacturing an inverter device according to any one of clauses to 18, wherein the heat dissipation layer includes a heat dissipation surface facing away from the first conductive layer and the second conductive layer in the first direction, and
in the third step, the bonding material is provided such that a surface roughness of a surface of the bonding material on the first side in the first direction is smaller than a surface roughness of the heat dissipation surface.
Clause 20.

A vehicle comprising:
a drive source; and
the semiconductor device according to clause 13,
wherein the semiconductor device is electrically connected to the drive source.
Clause 21.

The semiconductor device according to clause 5, wherein the protective layer contain resin.
Clause 22.

The semiconductor device according to clause 21, wherein the protective layer is peelable from the bonding surface.
Clause 23.

The semiconductor device according to clause 22, wherein the protective layer has sulfurization resistance.
Clause 24.

The semiconductor device according to clause 11, wherein the intermediate layer has a dimension in the first direction smaller than a dimension of the bonding material in the first direction.
Clause 25.

The semiconductor device according to clause 11, wherein the heat dissipation layer contains copper.
Clause 26.

The semiconductor device according to clause 13, wherein the metal particles include copper.
Clause 27.

The semiconductor device according to clause 13, wherein the bonding material includes a first portion and a second portion spaced apart from each other in a direction orthogonal to the first direction,
as viewed in the first direction, the first conductive layer overlaps with the first portion, and
as viewed in the first direction, the second conductive layer overlaps with the second portion.
Clause 28.

The semiconductor device according to clause 13, further comprising:
a first terminal electrically connected to the first conductive layer; and
a second terminal electrically connected to the second conductive layer.
Clause 29.

The semiconductor device according to clause 28, wherein the first terminal and the second terminal are exposed from the sealing resin.
Clause 30.

The method for manufacturing an inverter device according to clause 17, wherein the metal particles include silver.
Clause 31.

The method for manufacturing an inverter device according to clause 19, wherein the third step includes disposing a protective layer covering the bonding material after disposing the bonding material on the heat dissipation layer on the first side in the first direction, and
the fourth step includes removing the protective layer by peeling before sintering the bonding material.
Clause 32.

A vehicle comprising:
a drive source; and
the inverter device according to clause 15,
wherein the inverter device is electrically connected to the drive source.

1. A semiconductor device comprising:
a base material including a heat dissipation layer;
a first conductive layer bonded to the base material;
a first semiconductor element bonded to the first conductive layer; and
a bonding material located on a side opposite to the first conductive layer with respect to the base material in a first direction, the bonding material being disposed on the heat dissipation layer,
wherein the bonding material includes metal particles.

2. The semiconductor device according to claim 1, further comprising a sealing resin covering the first semiconductor element,
wherein the heat dissipation layer includes a heat dissipation surface exposed from the sealing resin, and
the bonding material is disposed on the heat dissipation surface.

3. The semiconductor device according to claim 2, wherein the bonding material includes a bonding surface facing the same side as the heat dissipation surface in the first direction, and
the bonding surface has a surface roughness smaller than a surface roughness of the heat dissipation surface.

4. The semiconductor device according to claim 3, further comprising a protective layer covering the bonding surface.

5. The semiconductor device according to claim 4, wherein the protective layer is an insulator.

6. The semiconductor device according to claim 5, wherein, as viewed in the first direction, the protective layer extends outward beyond a peripheral edge of the bonding surface.

7. The semiconductor device according to claim 6, wherein the protective layer is in contact with the sealing resin.

8. The semiconductor device according to claim 3, wherein, as viewed in the first direction, the bonding material overlaps with an entirety of the heat dissipation surface.

9. The semiconductor device according to claim 3, wherein, as viewed in the first direction, the bonding material is located inward of a peripheral edge of the heat dissipation surface.

10. The semiconductor device according to claim 3, further comprising an intermediate layer located between the heat dissipation surface and the bonding material,
wherein the bonding material is in contact with the intermediate layer, and
the intermediate layer includes the same metal element as the metal particles.

11. The semiconductor device according to claim 10, wherein the intermediate layer is in contact with the heat dissipation surface, and
the intermediate layer includes a metal element different from a metal element included in the heat dissipation layer.

12. The semiconductor device according to claim 3, wherein the base material includes an insulating layer located on a side opposite to the bonding material with respect to the heat dissipation layer, and
the first conductive layer is bonded to the insulating layer.

13. The semiconductor device according to claim 12, further comprising:
a second conductive layer located on the same side as the first conductive layer with respect to the base material and bonded to the insulating layer; and
a second semiconductor element conductively bonded to the second conductive layer,
wherein the first semiconductor element is conductively bonded to the first conductive layer, and
the second semiconductor element is electrically connected to the first semiconductor element and is covered with the sealing resin.

14. The semiconductor device according to claim 13, wherein the metal particles include silver.

15. An inverter device comprising:
a heat sink;
a base material including a heat dissipation layer facing the heat sink in a first direction;
a first conductive layer and a second conductive layer located on a side opposite to the heat sink with respect to the base material and bonded to the base material;
a first semiconductor element conductively bonded to the first conductive layer;
a second semiconductor element conductively bonded to the second conductive layer;
a first signal terminal electrically connected to the first semiconductor element;
a second signal terminal electrically connected to the second semiconductor element;
a wiring board electrically connected to the first signal terminal and the second signal terminal; and
a bonding layer bonding the heat sink and the heat dissipation layer,
wherein the bonding layer includes a sintered body of metal particles.

16. A method for manufacturing an inverter device, the method comprising:
a first step of bonding a first conductive layer and a second conductive layer to a base material including a heat dissipation layer such that the first conductive layer and the second conductive layer are located on a side opposite to the heat dissipation layer in a first direction;
a second step of conductively bonding a first semiconductor element to the first conductive layer and conductively bonding a second semiconductor element to the second conductive layer;
a third step of disposing a bonding material on the heat dissipation layer on a first side in the first direction;
a fourth step of sintering the bonding material to bond a heat sink and the heat dissipation layer;
a fifth step of disposing a first signal terminal electrically connected to the first semiconductor element and a second signal terminal electrically connected to the second semiconductor element; and
a sixth step of disposing a wiring board electrically connected to the first signal terminal and the second signal terminal,
wherein the bonding material includes metal particles.

17. The method for manufacturing an inverter device according to claim 16, wherein the bonding material is a sheet including the metal particles, and
the third step includes attaching the sheet to the heat dissipation layer.

18. The method for manufacturing an inverter device according to claim 16, wherein the bonding material is a paste including the metal particles, and
the third step includes applying the paste to the heat dissipation layer and then drying the paste.

19. The method for manufacturing an inverter device according to claim 16, wherein the heat dissipation layer includes a heat dissipation surface facing away from the first conductive layer and the second conductive layer in the first direction, and
in the third step, the bonding material is provided such that a surface roughness of a surface of the bonding material on the first side in the first direction is smaller than a surface roughness of the heat dissipation surface.

20. A vehicle comprising:
a drive source; and
the semiconductor device according to claim 13,
wherein the semiconductor device is electrically connected to the drive source.
